(19) United States
(12) Patent Application Publication
(10) Pub. No.: US 2011/0117718 A1
(43) Pub. Date: May 19, 2011

(54) METHOD OF FORMING SEMICONDUCTOR DEVICE

(75) Inventors: Yoshitaka Nakamura, Tokyo (JP); Takahiro Suzuki, Tokyo (JP); Kazuo Nomura, Tokyo (JP); Keisuke Otsuka, Tokyo (JP)

(73) Assignee: ELPIDA MEMORY, INC., Tokyo (JP)

(21) Appl. No.: 12/627,555

(22) Filed: Nov. 30, 2009

(30) Foreign Application Priority Data
Nov. 19, 2009 (JP) 2009-263915

(51) Int. Cl. H01L 21/02; H01L 21/8242

(52) U.S. Cl. 438/387; 257/E21.011; 257/E21.647

(57) ABSTRACT

A method of forming a semiconductor device includes forming a hole in an insulating film, forming a first conductive film in the hole, removing at least a portion of the insulating film around the first conductive film, and reducing a thickness of the first conductive film to produce a second conductive film.

### BACKGROUND OF THE INVENTION

1. Field of the Invention

The present invention generally relates to a method of forming a semiconductor device. Specifically, the present invention relates to a method of forming a semiconductor device that includes a memory cell area and a peripheral circuit area. More specifically, the present invention relates to a method of forming a semiconductor device that includes a dynamic random access memory (DRAM). Furthermore specifically, the present invention relates to a method of forming a semiconductor device that includes a DRAM-LSI.

Priority is claimed on Japanese Patent Application No. 2009-263915, filed Nov. 19, 2009, the contents of which are incorporated herein by reference.

2. Description of the Related Art

A semiconductor memory device such as DRAM may include an array of memory cells. Each memory cell may include a selecting transistor and a capacitor. Shrinkage of memory cells can be realized by microprocessing techniques. As the dimensions of a memory cell are shrunken, the capacity of each memory cell will be decreased. It has been known that a crown capacitor can be used as a memory cell capacitor because the crown-shaped capacitor has a relatively large surface and a limited horizontal area. The crown-shaped capacitor has a bottom electrode which has inside and outside walls which face a dielectric material. The crown-shaped capacitor has a larger contact area, relative to the limited horizontal size.

Japanese Unexamined Patent Application, First Publication, No. 7-7084 discloses that a crown capacitor is used as a memory cell capacitor. This publication further discloses that the difference in level between a memory cell array area and a peripheral circuit area is reduced by using the crown capacitor. Reduction of the level difference will be effective to avoid any disconnection of a conductive layer, wherein the conductive layer extends over the memory cell array area and the peripheral circuit area. If the level difference were relatively large, then the disconnection would be caused at the boundary between the memory cell array area and the peripheral circuit area. Reduction of the level difference will also be effective to planarize the surface of the substrate over the memory cell array area and the peripheral circuit area.

The above publication further discloses that a channel is positioned at the boundary area between the memory cell area and the peripheral circuit area. The channel and a storage electrode are formed as follows. An insulating film is selectively removed to form at least one groove and a recess in the insulating film. A conductive material is formed entirely to fill the at least one groove and the recess. A wet etching process is carried out to selectively remove the conductive material, thereby forming a storage electrode in the recess and a channel in the at least one groove.

The above publication furthermore discloses that one or more grooves are formed for forming a channel therein, in order to avoid that the insulation material in the peripheral circuit area is removed by the wet etching process, even the insulation material has to reside after the wet etching process.

Shrinkage of the memory cell will cause the leakage of current from a memory cell capacitor and short circuit formation between a bottom electrode and a connection plug.

### SUMMARY

In one embodiment, a method of forming a semiconductor device may include, but is not limited to, the following processes. At least one capacitor hole and a groove are formed in an insulating film. The at least one capacitor hole is in a memory cell area. The groove surrounds the memory cell area in plan view. Conductive films are formed at least in the at least one capacitor hole and in the groove. An etching process is carried out using the conductive films as etching stoppers to selectively remove the insulating film in the memory cell area, while leaving the insulating film outside the groove. A thickness is reduced of at least the conductive film in the at least one capacitor hole.

In another embodiment, a method of forming a semiconductor device may include, but is not limited to, the following processes. A semiconductor substrate is prepared, which has a memory cell area, a boundary area, and a peripheral circuit area. The boundary area surrounds the memory cell area in plan view. The peripheral circuit area surrounds the boundary area. An inter-layer insulator is formed, which extends over the memory cell area, the boundary area, and the peripheral circuit area. At least one capacitor hole is formed in the inter-layer insulator in the memory cell area. A dummy bottom electrode groove is formed in the inter-layer insulator in the boundary area. Conductive films are formed at least in the at least one capacitor hole and in the groove. An etching process is carried out using the conductive films as etching stoppers to selectively remove the insulating film in the memory cell area, while leaving the insulating film outside the groove. A thickness is reduced of at least the conductive film in the at least one capacitor hole.

In still another embodiment, a method of forming a semiconductor device may include, but is not limited to, forming a hole in an insulating film, forming a first conductive film in the hole, removing at least a portion of the insulating film around the first conductive film, and reducing a thickness of the first conductive film to produce a second conductive film.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a fragmentary cross sectional elevation view illustrating a semiconductor device in accordance with a first embodiment of the present invention;

FIG. 2 is a fragmentary cross sectional elevation view illustrating a semiconductor device in a step involved in a method of forming the semiconductor device of FIG. 1;

FIG. 3 is a fragmentary plan view illustrating a memory cell area of the semiconductor device shown in FIG. 2;

FIG. 4 is a fragmentary cross sectional elevation view illustrating a semiconductor device in a step subsequent to the step of FIG. 2, involved in the method of forming the semiconductor device of FIG. 1;

FIG. 5 is a fragmentary cross sectional elevation view illustrating a semiconductor device in a step subsequent to the step of FIG. 4, involved in the method of forming the semiconductor device of FIG. 1;

FIG. 6 is a fragmentary plan view illustrating a memory cell area of the semiconductor device shown in FIG. 5;

FIG. 7 is a fragmentary cross sectional elevation view illustrating a semiconductor device in a step subsequent to the step of FIG. 5, involved in the method of forming the semiconductor device of FIG. 1;

FIG. 8 is a fragmentary cross sectional elevation view illustrating a semiconductor device in a step subsequent to the step of FIG. 7, involved in the method of forming the semiconductor device of FIG. 1;

FIG. 9 is a fragmentary plan view illustrating a memory cell area of the semiconductor device shown in FIG. 8;

FIG. 10 is a fragmentary cross sectional elevation view illustrating a semiconductor device in a step subsequent to the step of FIG. 8, involved in the method of forming the semiconductor device of FIG. 1;

FIG. 11A is a fragmentary cross sectional elevation view illustrating a semiconductor device in a step subsequent to the step of FIG. 10, involved in the method of forming the semiconductor device of FIG. 1;

FIG. 11B is a fragmentary cross sectional elevation view illustrating a semiconductor device in a modified step subsequent to the step of FIG. 10, involved in the modified method of forming the semiconductor device of FIG. 1;

FIG. 12 is a fragmentary plan view illustrating a memory cell area of the semiconductor device shown in FIG. 11A;

FIG. 13 is a fragmentary cross sectional elevation view illustrating a semiconductor device in a step subsequent to the step of FIG. 11A, involved in the method of forming the semiconductor device of FIG. 1;

FIG. 14 is a fragmentary plan view illustrating a memory cell area of the semiconductor device shown in FIG. 13;

FIG. 15 is a fragmentary cross sectional elevation view illustrating a semiconductor device in a step subsequent to the step of FIG. 13, involved in the method of forming the semiconductor device of FIG. 1;

FIG. 16 is a fragmentary cross sectional elevation view illustrating a semiconductor device in a step subsequent to the step of FIG. 15, involved in the method of forming the semiconductor device of FIG. 1;

FIG. 17 is a fragmentary cross sectional elevation view illustrating a semiconductor device in a step subsequent to the step of FIG. 16, involved in the method of forming the semiconductor device of FIG. 1;

FIG. 18 is a fragmentary cross sectional elevation view illustrating a semiconductor device in a step subsequent to the step of FIG. 17, involved in the method of forming the semiconductor device of FIG. 1;

FIG. 19 is a fragmentary cross sectional elevation view illustrating a semiconductor device in a step subsequent to the step of FIG. 18, involved in the method of forming the semiconductor device of FIG. 1;

FIG. 20 is a diagram illustrating the number of cavities per wafer over thicknesses of the conductive films in the semiconductor devices;

FIG. 21 is a fragmentary cross sectional elevation view illustrating a semiconductor device in a step involved in a method of forming the semiconductor device in the related art; and

FIG. 22 is a fragmentary cross sectional elevation view illustrating a semiconductor device which is formed by the method shown in FIG. 21.

### DETAILED DESCRIPTION OF THE PREFERRED EMBODIMENTS

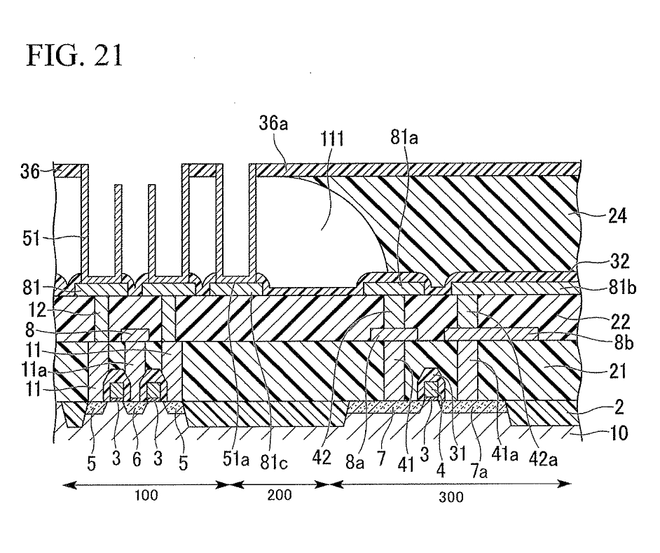

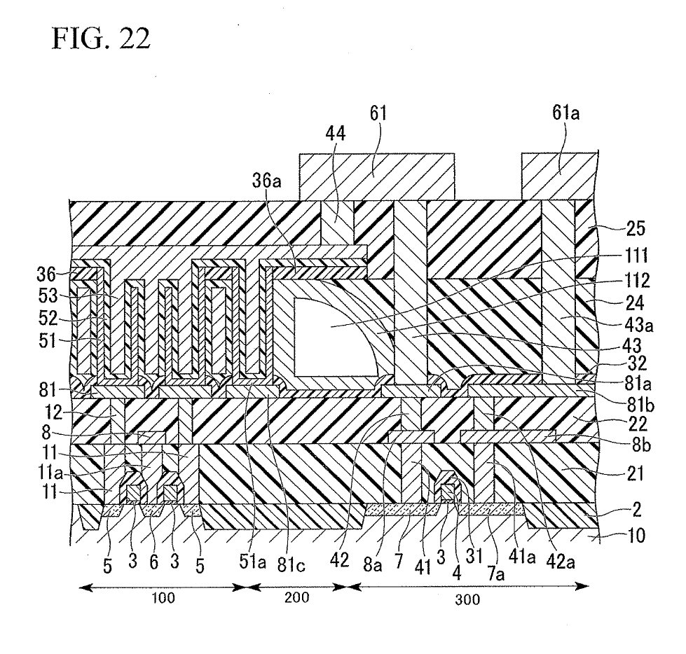

Before describing the present invention, the related art will be explained in detail with reference to FIGS. 21 and 22, in order to facilitate the understanding of the present invention.

FIG. 21 is a fragmentary cross sectional elevation view illustrating a semiconductor device in a step involved in a method of forming the semiconductor device in the related art. FIG. 22 is a fragmentary cross sectional elevation view illustrating a semiconductor device which is formed by the method shown in FIG. 21.

With reference to FIG. 22, a semiconductor device has a memory cell area 100, a boundary area 200, and a peripheral circuit/logic circuit area 300. The memory cell area 100 and the peripheral circuit/logic circuit area 300 are separated from each other by the boundary area 200. The semiconductor device includes a substrate 10. The substrate 10 may be a silicon substrate having a main surface. The substrate 10 has the memory cell area 100, the boundary area 200, and the peripheral circuit/logic circuit area 300. The semiconductor device includes isolation layers 2 which are disposed on the main surface of the substrate 10. The isolation layers 2 define a first active region in the memory cell area 100 and a second active region in the peripheral circuit/logic circuit area 300.

The memory cell area 100 of the semiconductor device will be described. The semiconductor device includes two selecting transistors which are disposed in the first active region in the memory cell area 100. Each of the two transistors is formed on the main surface of the first active region of the silicon substrate 10. The transistor includes a gate insulating film 3, a gate electrode 4 and source and drain diffusion regions 5 and 6. The gate insulating film 3 is disposed on the main surface of the substrate 10. The gate electrode 4 is disposed on the gate insulating film 3. The source and drain diffusion regions 5 and 6 are disposed in the substrate 10.

The semiconductor device includes inter-layer insulators 31 and 21. The inter-layer insulators 31 cover the gate electrodes 4. The inter-layer insulator 21 extends over the memory cell area 100, the boundary area 200 and the peripheral circuit/logic circuit area 300. The inter-layer insulator 21 is disposed over the source and drain diffusion regions 5 and 6 and the inter-layer insulators 31 as well as over the isolation layers 2. The semiconductor device includes a contact plug 11a which penetrates the inter-layer insulator 21. The contact plug 11a contacts the diffusion region 6. The semiconductor device includes a bit line 8 which runs over the inter-layer insulator 21. The bit line 8 is electrically connected through the contact plug 11a to the diffusion region 6. The semiconductor device includes contact plugs 11 which penetrate the inter-layer insulator 21. The contact plugs 11 contact the diffusion regions 5.

The semiconductor device includes an inter-layer insulator 22 which extends over the inter-layer insulator 21. The inter-layer insulator 22 covers the bit line 8. The semiconductor device includes contact plugs 12 which penetrate the inter-layer insulator 22. The contact plugs 12 contact the contact plugs 11. The contact plugs 12 are electrically connected through the contact plugs 11 to the diffusion regions 5.

The semiconductor device includes landing pads 81 over the inter-layer insulator 22. The landing pads 81 contact the contact plugs 12. The landing pads 81 are electrically connected through the contact plugs 12 and the contact plugs 11 to the diffusion regions 5. The semiconductor device includes an inter-layer insulator 32 which covers the landing pads 81. The semiconductor device includes an inter-layer insulator 24 which extends over the inter-layer insulator 32.

The semiconductor device includes capacitors which are disposed over the inter-layer insulator 22 and the inter-layer insulator 32. The capacitors are disposed in the inter-layer insulator 24. Each capacitor includes a bottom electrode 51, a capacitive insulating film 52, and a top electrode 53. The capacitive insulating film may be called to as a dielectric film. The top electrode 53 is a common electrode to the capacitors. The bottom electrode 51 and the top electrode 53 are electrically separated from each other by the capacitive insulating film 52. The bottom electrode 51 may have a cylindrical cup shape. The bottom electrode 51 contacts the landing pad 81. The bottom electrode 51 is electrically connected through the landing pads 81, the contact plugs 12 and the contact plugs 11 to the diffusion regions 5.

The semiconductor device includes an inter-layer insulator 25 which extends over the top electrode 53. The top electrode 53 is covered by the inter-layer insulator 25. The semiconductor device includes a contact plug 44 which penetrates the inter-layer insulator 25. The contact plug 44 contacts the top electrode 53. The semiconductor device includes a second level wiring 61 which runs over the inter-layer insulator 25. The second level wiring 61 contacts the contact plug 44. The second level wiring 61 is electrically connected through the contact plug 44 to the top electrode 53.

The semiconductor device includes inter-layer insulators 36 which act as beams. The inter-layer insulators 36 mechanically support the bottom electrodes 51. The inter-layer insulator 36 keeps a constant distance between the bottom electrodes 51. The inter-layer insulator 36 prevents the bottom electrodes 51 from contacting each other. The inter-layer insulator 36 prevents the bottom electrodes 51 from inclining or collapsing.

The peripheral circuit/logic circuit area 300 of the semiconductor device will be described. The semiconductor device includes a transistor that is included in peripheral circuits. The transistor includes a gate insulating film 3, a gate electrode 4 and source and drain diffusion regions 7 and 7a. The gate insulating film 3 is disposed on the main surface of the substrate 10. The gate electrode 4 is disposed on the gate insulating film 3. The source and drain diffusion regions 5 and 6 are disposed in the substrate 10.

The semiconductor device includes the inter-layer insulators 31 and 21. The inter-layer insulators 31 cover the gate electrodes 4. The inter-layer insulator 21 extends over the memory cell area 100, the boundary area 200 and the peripheral circuit/logic circuit area 300. The inter-layer insulator 21 is disposed over the source and drain diffusion regions 7 and 7a and the inter-layer insulators 31 as well as over the isolation layers 2. The semiconductor device includes contact plugs 41 and 41a which penetrate the inter-layer insulator 21. The contact plug 41 contacts the diffusion region 7. The contact plug 41a contacts the diffusion region 7a. The semiconductor device includes first level writings 8a and 8b which run over the inter-layer insulator 21. The first level writing 8a contacts the contact plug 41. The first level writing 8b contacts the contact plug 41a. The first level writing 8a is electrically connected through the contact plug 41 to the diffusion region 7. The first level writing 8b is electrically connected through the contact plug 41a to the diffusion region 7a.

The semiconductor device includes the inter-layer insulator 22 which extends over the inter-layer insulator 21. The inter-layer insulator 22 covers the first level writings 8a and 8b. The semiconductor device includes contact plugs 42 and 42a which penetrate the inter-layer insulator 22. The contact plug 42 contacts the first level writing 8a. The contact plug 42a contacts the first level writing 8b. The contact plug 42 is electrically connected through the first level writing 8a and the contact plug 41 to the diffusion region 7. The contact plug 42a is electrically connected through the first level writing 8b and the contact plug 41a to the diffusion region 7a.

The semiconductor device includes local wirings 81a and 81b over the inter-layer insulator 22. The local wiring 81a contacts the contact plug 42. The local wiring 81a is electrically connected through the contact plug 42 and the contact plugs 41 to the diffusion regions 7. The local wiring 81b contacts the contact plug 42a. The local wiring 81b is electrically connected through the contact plug 42a and the contact plugs 41a to the diffusion regions 7a.

The semiconductor device includes an inter-layer insulator 32 which covers the local wirings 81a and 81b. The semiconductor device includes the inter-layer insulator 24 over the inter-layer insulator 32. The semiconductor device includes the inter-layer insulator 25 over the inter-layer insulator 24. The semiconductor device includes contact plugs 43 and 43a which penetrate the inter-layer insulators 24, 25 and 32. The contact plug 43 contacts the local wiring 81a. The contact plug 43 is electrically connected through the local wiring 81a, the contact plug 42, the first level writing 8a, and the contact plug 41 to the diffusion region 7. The contact plug 43a contacts the local wiring 81b. The contact plug 43a is electrically connected through the local wiring 81b, the contact plug 42a, the first level writing 8b, and the contact plug 41a to the diffusion region 7a.

As described above, the second level wiring 61 runs over the inter-layer insulator 25. The second level wiring 61 contacts the contact plug 44. The second level wiring 61 is electrically connected through the contact plug 44 to the top electrode 53. The second level wiring 61 contacts the contact plug 43. The second level wiring 61 is electrically connected through the contact plug 43a, the local wiring 81b, the contact plug 42a, the first level writing 8b, and the contact plug 41a to the diffusion region 7a. The second level wiring 61 electrically connects the contact plug 44 and the contact plug 43. Thus, the top electrode 53 of the capacitors is eclectically connected through the contact plug 44, the second level wiring 61, the contact plug 43a, the local wiring 81b, the contact plug 42a, the first level writing 8b, and the contact plug 41a to the diffusion region 7a. In the memory cell area 100, the transistors are connected to the capacitors. The capacitors in the memory cell area 100 are electrically connected to the transistor in the peripheral circuit/logic circuit area 300.

The semiconductor device includes a second level wiring 61a which runs over the inter-layer insulator 24. The second level wiring 61a contacts the contact plug 43a. The second level wiring 61a is electrically connected through the contact plug 43a, the local wiring 81b, the contact plug 42a, the first level writing 8b and the contact plug 41a to the diffusion region 7a.

The boundary area 200 of the semiconductor device will be described. The boundary area 200 is positioned between the memory cell area 100 and the peripheral circuit/logic circuit area 300. In the boundary area 200, the semiconductor device includes a dummy bottom electrode 51a which surrounds the memory cell area 100. The dummy bottom electrode 51a has a frame-shape in plan view, so that the frame surrounds the memory cell area 100. The dummy bottom electrode 51a has a grove-shape in cross sectioned view. The dummy bottom electrode 51a forms a grove or a channel which extends to surround the memory cell area 100 in plan view. The semiconductor device includes a base 81c over the inter-layer insulator 22. The dummy bottom electrode 51a is disposed over the base 81c. The dummy bottom electrode 51a is separated from the top electrode 53 by the capacitive insulating film 52.

In the boundary area 200, the semiconductor device includes a cavity 111 and a conductive film 112. The conductive film 112 may be made of a metal. The cavity 111 has an inside wall on which the conductive film 112 extends. The cavity 111 with the conductive film 112 is positioned over the inter-layer insulator 32. The cavity 111 with the conductive film 112 is positioned between the dummy bottom electrode 51a and the contact plug 43. The conductive film 112 contacts the side face of the dummy bottom electrode 51a. The conductive film 112 contacts the side face of the contact plug 43. The dummy bottom electrode 51a and the contact plug 43 are electrically connected to each other through the conductive film 112.

The semiconductor device shown in FIG. 22 can be formed as follows. The semiconductor device has the elements which are positioned below the inter-layer insulator 24. The lower elements positioned below the inter-layer insulator 24 will be conveniently called to as lower elements. The lower elements positioned below the inter-layer insulator 24 are formed, before the inter-layer insulator 24 is then formed entirely over the lower elements over the substrate 10. The inter-layer insulator 24 is selectively removed to from capacitor holes and a dummy bottom electrode groove therein. The capacitor holes may be cylindrically shaped in plan view. The capacitor holes each define a capacitor. The dummy bottom electrode groove may be shaped in a frame which surrounds the memory cell area 100 in plan view. The dummy bottom electrode groove defines the dummy bottom electrode 51a.

Conductive layers are formed in the capacitor holes and the dummy bottom electrode groove, thereby forming the bottom electrodes 51 in the capacitor holes and the dummy bottom electrode 51a in the dummy bottom electrode groove.

As shown in FIG. 21, the inter-layer insulator 24 is selectively etched by an isotropic etching process. The inter-layer insulator 24 in the memory cell area 100 is isotropically etched to form a cavity 111 in the inter-layer insulator 24, so that the bottom electrodes 51 and the dummy bottom electrode 51a are exposed. Actually, however, the isotropic etching process can be carried out by a wet etching process using an etchant. The etchant may unintentionally penetrate the side wall of the dummy bottom electrodes 51a, so that the etchant isotropically etches the inter-layer insulator 24 in the boundary area 200. The isotropic etching process unintentionally forms a cavity 111 in the inter-layer insulator 24 in the boundary area 200 and a part of the peripheral circuit/logic circuit area 300. The cavity 111 is adjacent to the dummy bottom electrode 51a. The cavity 111 is positioned over the inter-layer insulator 32. The cavity 111 is adjacent to the side face toward the peripheral circuit/logic circuit area 300. The top of the cavity 111 reaches the inter-layer insulator 36a. The cavity 111 extends from the boundary area 200 to the peripheral circuit/logic circuit area 300. The cavity 111 is defined by the inter-layer insulators 24, 32, and 36a and also defined by the outside wall which faces toward the peripheral circuit/logic circuit area 300.

As described above, the cavity 111 extends from the boundary area 200 to the peripheral circuit/logic circuit area 300. In some cases, a contact hole for the contact plug 43 in the peripheral circuit/logic circuit area 300 may be connected to the cavity 111, so that the conductive film 112 is formed in the same process for forming the contact plug 43 in the contact hole. The conductive film 112 covers the inside wall of the cavity 111. The conductive film 112 contacts the side wall of the dummy bottom electrodes 51a. The conductive film 112 contacts the contact plug 43. The dummy bottom electrode 51a and the contact plug 43 are electrically connected to each other through the conductive film 112 which covers the inside wall of the cavity 111. Namely, the conductive film 112 performs as a short circuit between the dummy bottom electrode 51a and the contact plug 43. This short circuit formation makes the semiconductor device defective, thereby reducing the yield of the semiconductor device.

In order to avoid this problem, it is necessary to avoid formation of the cavity 111. In order to avoid formation of the cavity 111, it is necessary to prevent etchant from penetrating the side wall of the dummy bottom electrode 51a. In order to avoid etchant from penetrating the side wall of the dummy bottom electrodes 51a, it may be effective to increase the thickness of the side wall of the dummy bottom electrode 51a. Namely, the dummy bottom electrode 51a with the increased thickness may perform as an etching stopper.

In view of process efficiency, it is preferable that the bottom electrodes 51 and the dummy bottom electrode 51a are formed in the same process. When the bottom electrodes 51 and the dummy bottom electrode 51a are formed in the same process, the following difficulty is caused. As the thickness of the bottom electrodes 51 and the dummy bottom electrode 51a is increased without increasing the horizontal dimension of the capacitor holes, the inside dimension of the bottom electrodes 51 is decreased. In case that the bottom electrodes 51 have a cylinder shape, the increase in the thickness of the bottom electrodes 51 without increasing the diameter of the capacitor holes or the outer diameter of the bottom electrodes 51, the inner diameter of the bottom electrodes 51 is decreased. Decreasing the inside dimension of the bottom electrodes 51 makes it difficult to form at good coverage the capacitive insulating film 52 and the top electrode 53 in the narrow inside space of the bottom electrodes 51. Decreasing the inside dimension of the bottom electrodes 51 may deteriorate the coverage of the capacitive insulating film 52 and the top electrode 53. In case that the bottom electrodes 51 have a cylinder shape, decreasing the inner diameter of the bottom electrodes 51 makes it difficult to form at good coverage the capacitive insulating film 52 and the top electrode 53 in the narrow inside space of the bottom electrodes 51. Decreasing the inner diameter of the bottom electrodes 51 may deteriorate the coverage of the capacitive insulating film 52 and the top electrode 53. Deterioration in the coverage of the capacitive insulating film 52 and the top electrode 53 may cause or increase the leakage of current inside the bottom electrodes 51.

For the purpose of keeping good coverage of the capacitive insulating film 52 and the top electrode 53, it is effective to enlarge the diameter of the capacitor holes or the outer diameter of the bottom electrodes 51. Enlargement of the diameter of the capacitor holes or the outer diameter of the bottom electrodes 51 makes it difficult to shrink the semiconductor device.

The above-described process shown in FIG. 22 causes the short circuit between the contact plug 43 and the dummy bottom electrode 51a. The above-described countermeasures to avoid the formation of the short circuit with concurrent formations of the bottom electrode 51 and the dummy bottom electrode 15a without increasing the capacitor hole dimension may also deteriorate the coverage of the capacitive insulating film 52 and the top electrode 53, thereby causing the leakage of current. Increase of the capacitor hole dimension to avoid the short circuit formation and the leakage of current makes it difficult to satisfy the requirement for shrinkage of the semiconductor device.

It is preferable that the bottom electrode and the dummy bottom electrode can be formed in the same process. It is also preferable that the outer dimension is not increased for shrinkage of the semiconductor device, while keeping the inner dimension large enough to keep good coverage of the capacitive insulating film and the top electrode film to avoid leakage of current. It is also preferable to avoid any formation of a cavity which extends from the boundary area 200 to the peripheral circuit/logic circuit area 300, thereby avoiding any formation of short circuit between the dummy bottom electrode in the boundary area 200 and the contact plug in the peripheral circuit/logic circuit area 300.

The invention will be now described herein with reference to illustrative embodiments. Those skilled in the art will recognize that many alternative embodiments can be accomplished using the teaching of the present invention and that the invention is not limited to the embodiments illustrated for explanatory purpose.

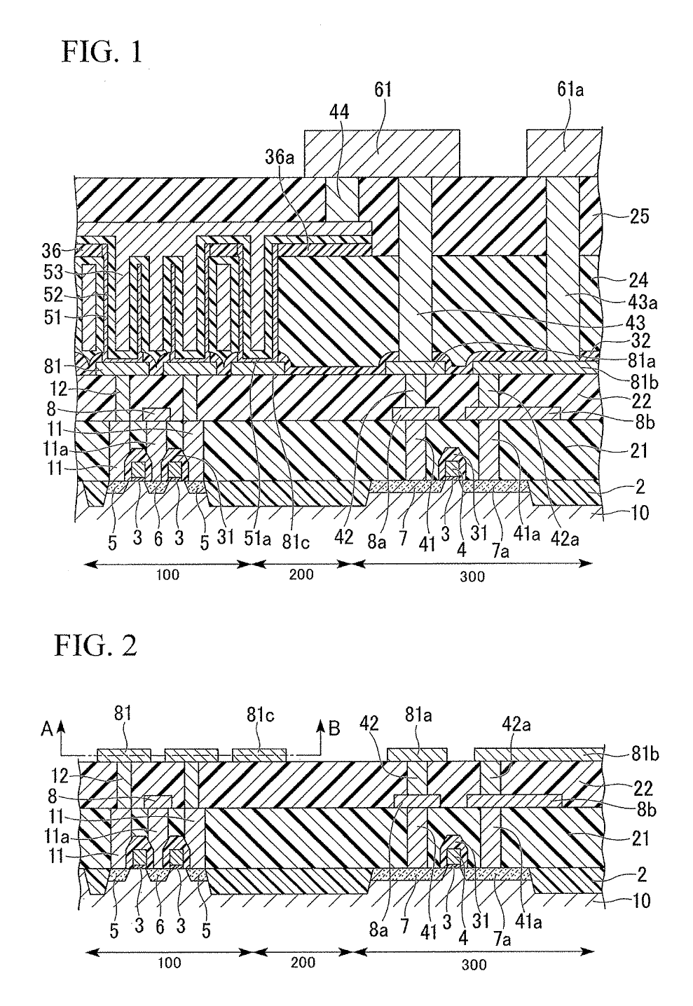

FIG. 1 is a fragmentary cross sectional elevation view illustrating a semiconductor device in accordance with a first embodiment of the present invention.

A semiconductor device has a memory cell area 100, a boundary area 200, and a peripheral circuit/logic circuit area 300. The memory cell area 100 and the peripheral circuit/logic circuit area 300 are separated from each other by the boundary area 200. The semiconductor device includes a substrate 10. The substrate 10 may be a silicon substrate having a main surface. The substrate 10 has the memory cell area 100, the boundary area 200, and the peripheral circuit/logic circuit area 300. The semiconductor device includes isolation layers 2 which are disposed on the main surface of the substrate 10. The isolation layers 2 define a first active region in the memory cell area 100 and a second active region in the peripheral circuit/logic circuit area 300.

The memory cell area 100 of the semiconductor device will be described. The semiconductor device includes two selecting transistors which are disposed in the first active region in the memory cell area 100. Each of the two transistors is formed on the main surface of the first active region of the silicon substrate 10. The transistor includes a gate insulating film 3, a gate electrode 4 and source and drain diffusion regions 5 and 6. The gate insulating film 3 is disposed on the main surface of the substrate 10. The gate electrode 4 is disposed on the gate insulating film 3. The source and drain diffusion regions 5 and 6 are disposed in the substrate 10.

The semiconductor device includes inter-layer insulators 31 and 21. The inter-layer insulators 31 cover the gate electrodes 4. The inter-layer insulator 21 extends over the memory cell area 100, the boundary area 200 and the peripheral circuit/logic circuit area 300. The inter-layer insulator 21 is disposed over the source and drain diffusion regions 5 and 6 and the inter-layer insulators 31 as well as over the isolation layers 2. The semiconductor device includes a contact plug 11a which penetrates the inter-layer insulator 21. The contact plug 11a contacts the diffusion region 6. The semiconductor device includes a bit line 8 which runs over the inter-layer insulator 21. The bit line 8 is electrically connected through the contact plug 11a to the diffusion region 6. The semiconductor device includes contact plugs 11 which penetrate the inter-layer insulator 21. The contact plugs 11 contact the diffusion regions 5. In some cases, the contact plugs 11 may be made of, but are not limited to, a polysilicon. The bit line 8 may be made of, but is not limited to, tungsten.

The semiconductor device includes an inter-layer insulator 22 which extends over the inter-layer insulator 21. The inter-layer insulator 22 covers the bit line 8. The semiconductor device includes contact plugs 12 which penetrate the inter-layer insulator 22. The contact plugs 12 contact the contact plugs 11. The contact plugs 12 are electrically connected through the contact plugs 11 to the diffusion regions 5.

The semiconductor device includes landing pads 81 over the inter-layer insulator 22. The landing pads 81 contact the contact plugs 12. The landing pads 81 are electrically connected through the contact plugs 12 and the contact plugs 11 to the diffusion regions 5. The semiconductor device includes an inter-layer insulator 32 which covers the landing pads 81. The semiconductor device includes an inter-layer insulator 24 which extends over the inter-layer insulator 32.

The semiconductor device includes capacitors which are disposed over the inter-layer insulator 22 and the inter-layer insulator 32. The capacitors are disposed in the inter-layer insulator 24. Each capacitor includes a bottom electrode 51, a capacitive insulating film 52, and a top electrode 53. The top electrode 53 is a common electrode to the capacitors. The bottom electrode 51 and the top electrode 53 are electrically separated from each other by the capacitive insulating film 52. The bottom electrode 51 may have a cylindrical cup shape. The bottom electrode 51 has a bottom wall which contacts the landing pad 81. The bottom electrode 51 has a side wall which extends upwardly. The lower portion of the side wall of the bottom electrode 51 is covered by the inter-layer insulator 32. Of the bottom electrode 51, the bottom wall and the lower portion of the side wall are thicker than the other portion of the side wall than the lower portion. The inter-layer insulator 32 may perform as an etching stopper. The inter-layer insulator 32 may be made of, but is not limited to, silicon nitride. The bottom electrode 51 is electrically connected through the landing pads 81, the contact plugs 12 and the contact plugs 11 to the diffusion regions 5. The bottom electrode 51 may be made of, but is not limited to, titanium nitride.

The semiconductor device includes inter-layer insulators 36 which act as beams. The inter-layer insulators 36 mechanically support the bottom electrodes 51. The inter-layer insulator 36 keeps a constant distance between the bottom electrodes 51. The inter-layer insulator 36 prevents the bottom electrodes 51 from contacting each other. The inter-layer insulator 36 prevents the bottom electrodes 51 from inclining or collapsing. The inter-layer insulator 36 may perform as an etching stopper.

The capacitive insulating film 52 may have a multi-layered structure of dielectric or insulator. In some cases, the capacitive insulating film 52 may include, but is not limited to, an aluminum oxide film and a zirconium oxide film. The capacitive insulating film 52 may extend over the memory cell area 100 and the boundary area 200. The capacitive insulating film 52 extends along the inside and outside walls of the bottom electrodes 51. The capacitive insulating film 52 also extends over the inter-layer insulator 32. The capacitive insulating film 52 also extends the inside and outside walls of the dummy bottom electrodes 51a. The capacitive insulating film 52 also extends over the inter-layer insulators 36 and 36a.

The top electrode 53 may include a conductive film. The top electrode 53 may be made of, but is not limited to, titanium nitride. The top electrode 53 extends over the memory cell area 100 and the boundary area 200. The top electrode 53 contacts the capacitive insulating film 52. The top electrode 53 extends along the capacitive insulating film 52. The top electrode 53 is separated by the capacitive insulating film 52 from the bottom electrodes 51 and the dummy bottom electrode 51a. The top electrode 53 with the capacitive insulating film 52 fill the inside spaces of the bottom electrodes 51 and the dummy bottom electrode 51a.

The outside face of the dummy bottom electrode 51a contacts the inter-layer insulator 24. The bottom electrode 51 has a bottom surface which contacts the landing pad 81. The bottom electrode 51 is electrically connected through the landing pad 81 to the contact plug 12. The landing pad 81 provides a sufficiently large contact area between the bottom electrode 51 and the contact plug 12, thereby ensuring the electrical connection between the bottom electrode 51 and the contact plug 12. The contact plug 12 contacts the contact plug 11. The contact plug 11 contacts the diffusion region 5. The contact plug 11 may be made of, but is not limited to, a polysilicon. The bottom electrode 51 is eclectically connected through the contact plug 12 to the diffusion region 5.

The semiconductor device includes an inter-layer insulator 25 which extends over the top electrode 53. The top electrode 53 is covered by the inter-layer insulator 25. The semiconductor device includes a contact plug 44 which penetrates the inter-layer insulator 25. The contact plug 44 contacts the top electrode 53. The semiconductor device includes a second level wiring 61 which runs over the inter-layer insulator 25. The second level wiring 61 contacts the contact plug 44. The second level wiring 61 is electrically connected through the contact plug 44 to the top electrode 53.

The peripheral circuit/logic circuit area 300 of the semiconductor device will be described. The semiconductor device includes a transistor that is included in peripheral circuits. The peripheral circuit/logic circuit area 300 has an active region defined by the isolation film 2. The semiconductor substrate 10 in the active region has the main surface. The transistor includes a gate insulating film 3, a gate electrode 4 and source and drain diffusion regions 7 and 7a. The gate insulating film 3 is disposed on the main surface of the substrate 10. The gate electrode 4 is disposed on the gate insulating film 3. The source and drain diffusion regions 5 and 6 are disposed in the substrate 10.

The semiconductor device includes the inter-layer insulators 31 and 21. The inter-layer insulators 31 cover the gate electrodes 4. The inter-layer insulator 21 extends over the memory cell area 100, the boundary area 200 and the peripheral circuit/logic circuit area 300. The inter-layer insulator 21 is disposed over the source and drain diffusion regions 7 and 7a and the inter-layer insulators 31 as well as over the isolation layers 2. The semiconductor device includes contact plugs 41 and 41a which penetrate the inter-layer insulator 21. The contact plug 41 contacts the diffusion region 7. The contact plug 41a contacts the diffusion region 7a. The semiconductor device includes first level writings 8a and 8b which run over the inter-layer insulator 21. The first level writing 8a contacts the contact plug 41. The first level writing 8b contacts the contact plug 41a. The first level writing 8a is electrically connected through the contact plug 41 to the diffusion region 7. The first level writing 8b is electrically connected through the contact plug 41a to the diffusion region 7a.

The semiconductor device includes the inter-layer insulator 22 which extends over the inter-layer insulator 21. The inter-layer insulator 22 covers the first level writings 8a and 8b. The semiconductor device includes contact plugs 42 and 42a which penetrate the inter-layer insulator 22. The contact plug 42 contacts the first level writing 8a. The contact plug 42a contacts the first level writing 8b. The contact plug 42 is electrically connected through the first level writing 8a and the contact plug 41 to the diffusion region 7. The contact plug 42a is electrically connected through the first level writing 8b and the contact plug 41a to the diffusion region 7a. The semiconductor device includes local wirings 81a and 81b over the inter-layer insulator 22. The local wiring 81a contacts the contact plug 42. The local wiring 81a is electrically connected through the contact plug 42 and the contact plugs 41 to the diffusion regions 7. The local wiring 81b contacts the contact plug 42a. The local wiring 81b is electrically connected through the contact plug 42a and the contact plugs 41a to the diffusion regions 7a.

The semiconductor device includes an inter-layer insulator 32 which covers the local wirings 81a and 81b. The semiconductor device includes the inter-layer insulator 24 over the inter-layer insulator 32. The semiconductor device includes the inter-layer insulator 25 over the inter-layer insulator 24. The semiconductor device includes contact plugs 43 and 43a which penetrate the inter-layer insulators 24, 25 and 32. The contact plug 43 contacts the local wiring 81a. The contact plug 43 is electrically connected through the local wiring 81a, the contact plug 42, the first level writing 8a, and the contact plug 41 to the diffusion region 7. The contact plug 43a contacts the local wiring 81b. The contact plug 43a is electrically connected through the local wiring 81b, the contact plug 42a, the first level writing 8b, and the contact plug 41a to the diffusion region 7a.

As described above, the second level wiring 61 runs over the inter-layer insulator 25. The second level wiring 61 contacts the contact plug 44. The second level wiring 61 is electrically connected through the contact plug 44 to the top electrode 53. The second level wiring 61 contacts the contact plug 43. The second level wiring 61 is electrically connected through the contact plug 43a, the local wiring 81b, the contact plug 42a, the first level writing 8b, and the contact plug 41a to the diffusion region 7a. The second level wiring 61 electrically connects the contact plug 44 and the contact plug 43. Thus, the top electrode 53 of the capacitors is eclectically connected through the contact plug 44, the second level wiring 61, the contact plug 43a, the local wiring 81b, the contact plug 42a, the first level writing 8b, and the contact plug 41a to the diffusion region 7a. In the memory cell area 100, the transistors are connected to the capacitors. The capacitors in the memory cell area 100 are electrically connected to the transistor in the peripheral circuit/logic circuit area 300.

The semiconductor device includes a second level wiring 61a which runs over the inter-layer insulator 24. The second level wiring 61a contacts the contact plug 43a. The second level wiring 61a is electrically connected through the contact plug 43a, the local wiring 81b, the contact plug 42a, the first level writing 8b and the contact plug 41a to the diffusion region 7a.

The boundary area 200 of the semiconductor device will be described. The boundary area 200 is positioned between the memory cell area 100 and the peripheral circuit/logic circuit area 300. In the boundary area 200, the semiconductor device includes a dummy bottom electrode 51a which surrounds the memory cell area 100. The dummy bottom electrode 51a has a frame-shape in plan view, so that the frame surrounds the memory cell area 100. The dummy bottom electrode 51a has a grove-shape in cross sectioned view. The dummy bottom electrode 51a forms a grove or a channel which extends to surround the memory cell area 100 in plan view. The semiconductor device includes a base 81c over the inter-layer insulator 22. The dummy bottom electrode 51a is disposed over the base 81c. The dummy bottom electrode 51a is separated from the top electrode 53 by the capacitive insulating film 52.

The dummy bottom electrode 51a includes an inside wall, an outside wall and a bottom wall. The inside and outside walls of the dummy bottom electrode 51a extend upwardly. The inside wall of the dummy bottom electrode 51a includes a first portion and a second portion. The first portion of the inside wall contacts the inter-layer insulators 36 and 32. The second portion of the inside wall do not contact the inter-layer insulators 36 and 32. The second portion of the inside wall is thinner than the first portion of the inside wall. The first portion is thicker than the second portion. The bottom wall is thicker than the second portion. The outside wall of the dummy bottom electrode 51a contacts the inter-layer insulators 32, 24 and 36. The outside wall and the inside wall have inside faces which face toward each other. The outside wall has an outer surface which faces toward the peripheral circuit/logic circuit area 300.

The base 81c and the landing pads 81 are provided to allow that the capacitor holes and the dummy bottom electrode groove are formed in the inter-layer insulator 24 in the same process.

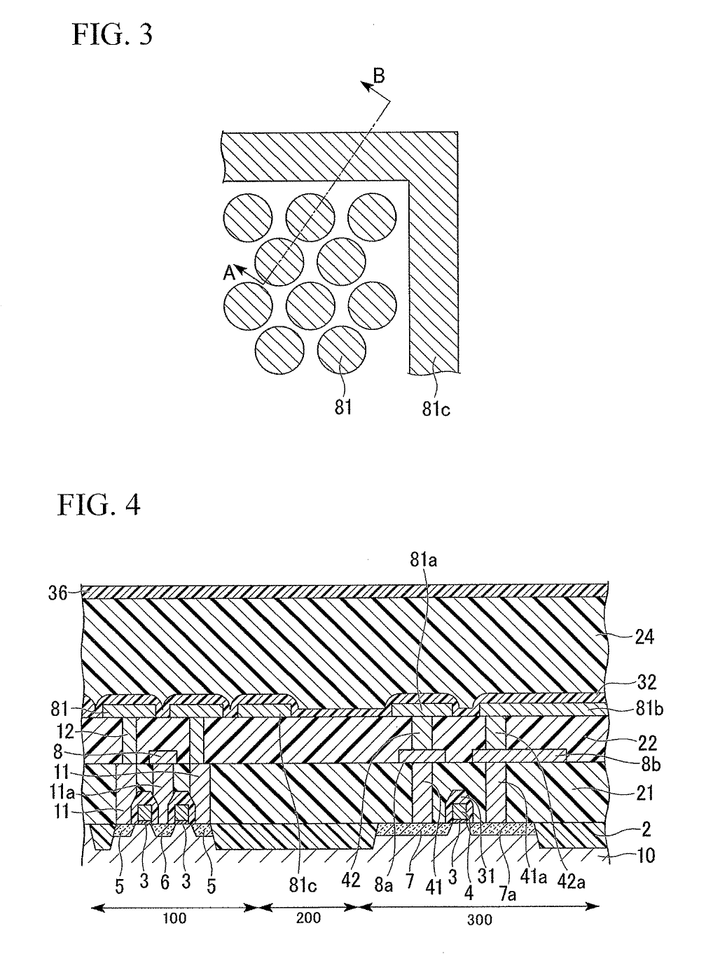

A method of forming the semiconductor device shown in FIG. 1 will be described. FIG. 2 is a fragmentary cross sectional elevation view illustrating a semiconductor device in a step involved in a method of forming the semiconductor device of FIG. 1. FIG. 3 is a fragmentary plan view illustrating a memory cell area of the semiconductor device shown in FIG. 2.

A semiconductor substrate 10 is prepared. Typically, the semiconductor substrate is a silicon substrate. The semiconductor substrate 10 has a main surface. Isolation films 2 are selectively formed on the main surface of the semiconductor substrate 10. The isolation films 2 define active regions in the memory cell area 100 and the peripheral circuit/logic circuit area 300. The isolation films 2 also define the memory cell area 100, the boundary area 200, and the peripheral circuit/logic circuit area 300.

Gate insulating films 3 are formed on the main surfaces of the active regions in the memory cell area 100 and the peripheral circuit/logic circuit area 300 in the same process. Gate electrodes 4 are formed on the gate insulating films 3 of the memory cell area 100 and the peripheral circuit/logic circuit area 300 in the same process. Diffusion regions 5 and 6 and diffusion regions 7 and 7a are formed in the active regions of the memory cell area 100 and the peripheral circuit/logic circuit area 300 in the same process. The diffusion regions 5 and 6 are formed in the active region of the memory cell area 100. The diffusion regions 7 and 7a are formed in the active region of the peripheral circuit/logic circuit area 300. The transistors are formed in the active regions of the memory cell area 100 and the peripheral circuit/logic circuit area 300 in the same processes.

An inter-layer insulator 31 is formed over the substrate 10, so that the inter-layer insulator 31 covers the gate electrodes 4. The inter-layer insulator 31 may be made of, but is not limited to, silicon nitride. An inter-layer insulator 21 is formed over the inter-layer insulator 31. The inter-layer insulator 21 may be made of, but is not limited to, silicon oxide. The inter-layer insulator 21 is planarized to form a flat upper surface. Contact holes are formed in the inter-layer insulator 21. The contact holes penetrate the inter-layer insulator 21. The contact holes are positioned over the diffusion regions 5 and 6 in the memory cell area 100, so that parts of the diffusion regions 5 and 6 are exposed to the contact holes. The other contact holes are positioned over the diffusion regions 7 and 7a in the peripheral circuit/logic circuit area 300, so that parts of the diffusion regions 7 and 7a are exposed to the contact holes. The contact holes in the memory cell area 100 and the peripheral circuit/logic circuit area 300 are filled with a conductive material. The conductive material contact the diffusion regions 5 and 6 in the memory cell area 100 and the conductive material contact the diffusion regions 7 and 7a in the peripheral circuit/logic circuit area 300. As a result, contact plugs 11, 11a, 14, and 14a are formed in the contact holes by the same processes. The contact plugs 11 11a are formed in the memory cell area 100. The contact plugs 14 and 14a are formed in the peripheral circuit/logic circuit area 300. The contact plugs 11 contact the diffusion regions 5 in the memory cell area 100. The contact plug 11a contacts the diffusion region 6 in the memory cell area 100. The contact plugs 41 contacts the diffusion region 7 in the peripheral circuit/logic circuit area 300. The contact plugs 41a contacts the diffusion region 7a in the peripheral circuit/logic circuit area 300.

A conductive layer is formed over the inter-layer insulator 21. The conductive layer is then patterned to form a bit line 8 in the memory cell area 100 and first level wiring layers 8a and 8b in the peripheral circuit/logic circuit area 300. The bit line 8 and the first level wiring layers 8a and 8b are formed by the same processes. The bit line 8 and the first level wiring layers 8a and 8b are preferably made of the same conductive material and formed by the same processes. It is also possible that the bit line 8 and the first level wiring layers 8a and 8b are made of different conductive materials and formed by separate processes.

An inter-layer insulator 22 is formed over the inter-layer insulator 21, so that the inter-layer insulator 22 covers the bit line 8 and the first level wiring layers 8a and 8b. The inter-layer insulator 22 may be made of, but is not limited to, silicon oxide. Contact holes are formed in the inter-layer insulator 22. The contact holes penetrate the inter-layer insulator 22. The contact holes are positioned over the contact plugs 11 in the memory cell area 100, so that parts of the contact plugs 11 are exposed to the contact holes. The other contact holes are positioned over the first level wiring layers 8a and 8b in the peripheral circuit/logic circuit area 300, so that parts of the first level wiring layers 8a and 8b are exposed to the contact holes.

A conductive material is formed in the contact holes and over the inter-layer insulator 22. The conductive material in the contact holes contacts the contact plugs 11 in the memory cell area 100 and the first level wiring layers 8a and 8b in the peripheral circuit/logic circuit area 300. The conductive material is polished so that the conductive material over the inter-layer insulator 22 is removed, while the conductive material remains in the contact holes, thereby forming contact plugs 12 in the memory cell area 100 and contact plugs 42 and 42a in the peripheral circuit/logic circuit area 300. The conductive material may be realized by, but not limited to, a multi-layered film. For example, the conductive material may be realized by, but not limited to, a titanium film, a titanium nitride film, and a tungsten film. The conductive multi-layered film is formed in the contact holes and over the inter-layer insulator 22. The conductive multi-layered film in the contact holes contact the contact plugs 11 in the memory cell area 100 and the first level wiring layers 8a and 8b in the peripheral circuit/logic circuit area 300. The conductive multi-layered film over the inter-layer insulator 22 is removed by a chemical mechanical polishing process, while the conductive multi-layered film remains in the contact holes. As a result, contact plugs 12, 42 and 42a are formed by the same processes. The contact plugs 12 are formed in the memory cell area 100. The contact plugs 12 contact the contact plugs 11 in the memory cell area 100. The contact plugs 42 and 42a are formed in the peripheral circuit/logic circuit area 300. The contact plugs 42 and 42a contact the first level wiring layers 8a and 8b in the peripheral circuit/logic circuit area 300.

A conductive layered film is formed over the inter-layer insulator 22 and over the contact plugs 12, 42 and 42a. The conductive layered film may be realized by, but is not limited to, a multi-layered film. A typical example of the multi-layered film may be a tungsten nitride film and a tungsten film. The tungsten nitride film and the tungsten film may be formed by a sputtering process. The conductive layered film is then patterned by a lithography process and a dry etching process, thereby forming landing pads 81 in the memory cell area 100, a base 81c in the boundary area 200, and local wirings 81a and 81b in the peripheral circuit/logic circuit area 300. The landing pads 81, the base 81c and local wirings 81a and 81b are formed by the same processes. The landing pads 81 contact the contact plugs 12 in the memory cell area 100. The base 81c is disposed over the inter-layer insulator 22 in the boundary area 200. The local wirings 81a and 81b contact the contact plugs 42 and 42a in the peripheral circuit/logic circuit area 300. As shown in FIG. 3, the landing pads 8 may be disposed inside the base 81c which forms a frame surrounding the landing pads 8. The base 81c may form a rectangle frame in plan view. The landing pads 8 may each have a circular shape in plan view.

FIG. 4 is a fragmentary cross sectional elevation view illustrating a semiconductor device in a step subsequent to the step of FIG. 2, involved in the method of forming the semiconductor device of FIG. 1.

An inter-layer insulator 32 is formed over the inter-layer insulator 22, so that the inter-layer insulator 32 covers the landing pads 81, the base 81c and local wirings 81a and 81b. The inter-layer insulator 32 may perform as an etching stopper. In this case, the inter-layer insulator 32 may be made of, but is not limited to, a material which is much slower in etching rate to an etchant than the material of the inter-layer insulator 24. This etchant is used to etch the inter-layer insulator 24. The inter-layer insulator 32 can perform as an etching stopper to the etchant which is used to etch the inter-layer insulator 24. In some cases, the inter-layer insulator 24 may be made of, but is not limited to, silicon oxide. The etchant for etching the inter-layer insulator 24 may be, but is not limited to, a diluted hydrogen fluoride solution. The inter-layer insulator 32 may be made of, but is not limited to, silicon nitride. The inter-layer insulator 32 of silicon nitride may be formed by any available process such as a low pressure chemical vapor deposition process and an atomic layer deposition.

For the etching stopper, it is preferable to increase the thickness of the inter-layer insulator 32. Increase in the thickness of the inter-layer insulator 32 increases unworkable portions of the bottom electrodes 51. The unworkable portions are bottom electrode's portions which are surrounded by the inter-layer insulator 32. The unworkable portions do not effectively work as a bottom electrode. For ensuring sufficiently large capacity, it is not preferable to increase the thickness of the inter-layer insulator 32. Increase in the thickness of the inter-layer insulator 32 makes it difficult to form capacitor holes 91 which penetrate the inter-layer insulator 32 and other layers over it. Also, increase in the thickness of the inter-layer insulator 32 makes it difficult to form contact holes which penetrate the inter-layer insulator 32 and other layers over it for forming the contact plugs 43. In some cases, the thickness of the inter-layer insulator 32 may preferably be, but is not limited to, in the range of 15 nm to 150 nm, and more preferably about 50 nm.

An inter-layer insulator 24 is formed over the inter-layer insulator 32. The inter-layer insulator 24 may be made of, but is not limited to, silicon oxide. An inter-layer insulator 36 is formed over the inter-layer insulator 24. The inter-layer insulator 36 may be made of, but is not limited to, silicon nitride. The inter-layer insulator 36 may perform as an anti-etching film. The thickness of the inter-layer insulator 24 will define the height of the capacitors to be formed in the later processes. Increase in the thickness of the inter-layer insulator 24 will increase the height of the capacitors. Increase in the height of the capacitor increases the electrode area of the capacitor, namely the capacity of the capacitor. For increasing the capacity of each of the capacitors, it is preferable to increase the thickness of the inter-layer insulator 24. Increase in the thickness of the inter-layer insulator 24 will make it difficult to form capacitor holes 91 which penetrate the inter-layer insulator 24 and other layers over it. Also, increase in the thickness of the inter-layer insulator 24 makes it difficult to form contact holes which penetrate the inter-layer insulator 24 and other layers over it for forming the contact plugs 43. Also, increase in the thickness of the inter-layer insulator 32 makes it difficult to remove the inter-layer insulator 24 by a wet etching process.

The height of the capacitors or the thickness of the inter-layer insulator 24 may be determined in view of easiness to form capacitor holes 91 which are spatially separate from each other. In some cases, the height of the capacitors or the thickness of the inter-layer insulator 24 may preferably be, but is not limited to, in the range of 15 times to 35 times of a horizontal dimension or a diameter of the capacitor holes 91. More preferably, the height of the capacitors or the thickness of the inter-layer insulator 24 may be, but is not limited to, in the range of 15 times to 25 times of the horizontal dimension or the diameter of the capacitor holes 91. In one example, the diameter of the capacitor hole 91 may have, but is not limited to, 80 nm and the thickness of the inter-layer insulator 24 may be, but is not limited to, 1.5 micrometers. In this specification, for convenience, the height of the capacitors is approximately estimated to be equal to the thickness of the inter-layer insulator 24, although the height is more precisely equal to the total thickness of the inter-layer insulators 24, 32 and 36.

In some cases, the inter-layer insulator 24 may have a single-layered film. In other cases, the inter-layer insulator 24 may have a multi-layered film. The multi-layered film may include, but is not limited to, a boron phosphor silicate glass film (BPSG film) as a lower film and a plasma tetra ethoxy silane film (PTEOS film) as an upper layer. The boron phosphor silicate glass film (BPSG film) is a silicon dioxide film which contains boron and phosphorous.

If the dry etching technique is used to form the capacitor holes 91 in the inter-layer insulator 24, there is a tendency that an upper portion of capacitor hole 91 is larger in diameter than a lower portion thereof. In some cases, there may be a large difference in diameter between the upper portion and the lower portion of the capacitor hole 91. For example, the difference in diameter may be in the range of 10 nm to 30 nm. In case that the inter-layer insulator 24 is the double layered film of the BPSG film and the PTEOS film, there is a technique to reduce the difference in diameter between the upper portion and the lower portion of the capacitor hole 91. The dry etching technique is used to form the capacitor holes 91 in the inter-layer insulator 24. Then, a wet etching process is additionally carried out by using an etchant which is higher in etching rate to the BPSG film than to the PTEOS film. A typical example of the etchant, which is higher in etching rate to the BPSG film than to the PTEOS film, may be a diluted hydrogen fluoride solution. The wet etching process using this etchant being higher in etching rate to the BPSG film than to the PTEOS film causes that the BPSG film is isotropically etched at a higher etching rate than the etching rate at which PTEOS film being isotropically etched. This wet etching process will effectively reduce the difference in diameter between the upper portion and the lower portion of the capacitor hole 91.

The BPSG film is high in wet etching rate to the diluted hydrogen fluoride solution. Thus, use of the diluted hydrogen fluoride solution shortens the wet-etching time to etch the BPSG film. The inter-layer insulator 36 is performing as the etching stopper while the inter-layer insulator 24 is being wet-etched. Shortening the wet-etching time to etch the BPSG film in the inter-layer insulator 24 will allow for reducing the necessary thickness of the inter-layer insulator 36 as the etching stopper. Reducing the thickness of the inter-layer insulator 36 will make it easier to form a window 71 in the later processes.

An inter-layer insulator 36 is formed over the inter-layer insulator 24. The inter-layer insulator 36 may perform as an etching stopper when the inter-layer insulator 24 is wet-etched. In this case, the inter-layer insulator 36 may be made of, but is not limited to, a material which is much slower in etching rate to an etchant than the material of the inter-layer insulator 24. This etchant is used to etch the inter-layer insulator 24. The inter-layer insulator 36 can perform as an etching stopper to the etchant which is used to etch the inter-layer insulator 24. In some cases, the inter-layer insulator 24 may be made of, but is not limited to, silicon oxide. The etchant for etching the inter-layer insulator 24 may be, but is not limited to, a diluted hydrogen fluoride solution. The inter-layer insulator 36 may be made of, but is not limited to, silicon nitride. The inter-layer insulator 36 of silicon nitride may be formed by any available process such as a low pressure chemical vapor deposition process and an atomic layer deposition. If the inter-layer insulator 36 is made of silicon nitride and is formed by an atomic layer deposition process at a growth temperature of 550° C., the inter-layer insulator 36 is much slower in etching rate to the etchant of a diluted hydrogen fluoride than the silicon oxide film as the inter-layer insulator 24. In view of the etching stopper to the etchant of a diluted hydrogen fluoride, it is preferable that the inter-layer insulator 36 is made of silicon nitride and is formed by an atomic layer deposition process at a growth temperature of 550° C.

For convenience, the solution containing 49% by weight of hydrogen fluoride might be preferable as the etchant to etch the inter-layer insulator 24 while the inter-layer insulator 36 is performing as the etching stopper. The solution containing 49% by weight of hydrogen fluoride is commercially available and is useful without any modification thereto.

The inter-layer insulator 36 may perform as the etching stopper to the wet etching to the inter-layer insulator 24. The inter-layer insulator 36 may also perform as a mechanical supporter for mechanically supporting the bottom electrodes 51. For the etching stopper and the mechanical supporter in the form of a beam, it is preferable to increase the thickness of the inter-layer insulator 36. Increase in the thickness of the inter-layer insulator 36 makes it difficult to form a window 71 in the later processes. This makes it difficult to remove the inter-layer insulator 24 directly under the inter-layer insulator 36 which will perform as the beam or the mechanical supporter. In these viewpoints, it is preferable that the thickness of the inter-layer insulator 36 may be, but is not limited to, in the range of 20 nm to 200 nm. More preferably, the thickness of the inter-layer insulator 36 before the wet etching process for wet-etching the inter-layer insulator 24 may be at least 70 nm so as to ensure at least 40 nm of thickness of the inter-layer insulator 36 after the wet etching process. Furthermore preferably, the thickness of the inter-layer insulator 36 before the wet etching process for wet-etching the inter-layer insulator 24 may be, but is not limited to, about 100 nm, in view of the process margin.

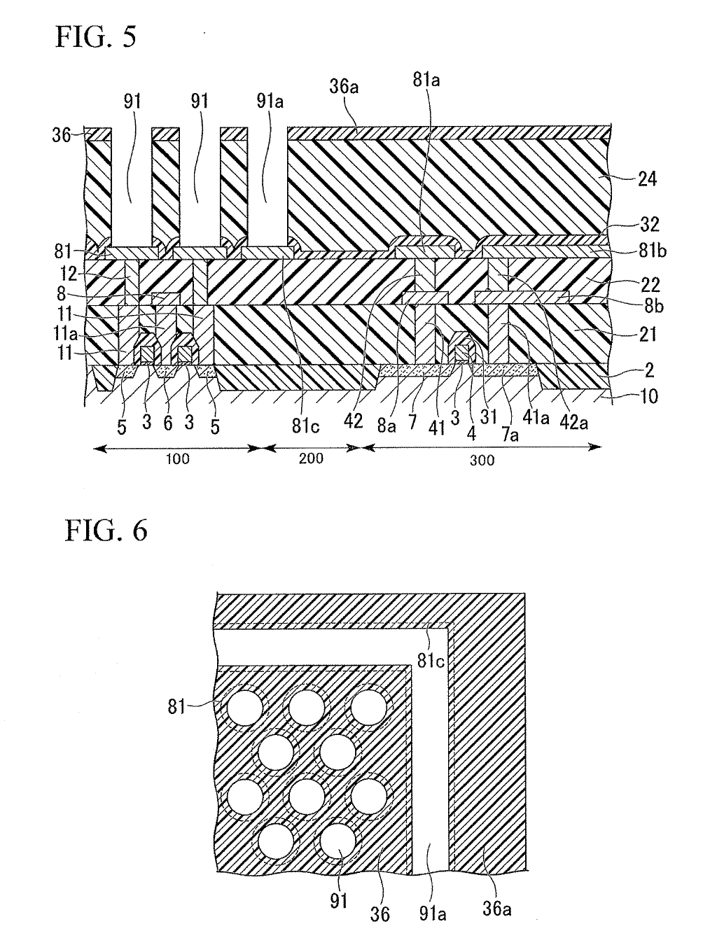

FIG. 5 is a fragmentary cross sectional elevation view illustrating a semiconductor device in a step subsequent to the step of FIG. 4, involved in the method of forming the semiconductor device of FIG. 1. FIG. 6 is a fragmentary plan view illustrating a memory cell area of the semiconductor device shown in FIG. 5.

Capacitor holes 91 and a dummy bottom electrode groove 91a are formed in the multi-layered structure of the inter-layer insulators 32, 24 and 36. The capacitor holes 91 are formed in the memory cell area 100. The dummy bottom electrode groove 91a is formed in the boundary area 200. The capacitor hole will define the shape of the bottom electrode 51 in plan view. The capacitor hole will define the horizontal dimensions such as a diameter of the bottom electrode 51. The dummy bottom electrode groove 91a will define the shape of the dummy bottom electrode 51a in plan view. The dummy bottom electrode groove 91a will define the horizontal dimensions of the dummy bottom electrode 51a. The dummy bottom electrode groove 91a surrounds in plan view the memory cell area 100 in which the capacitor holes 91 are formed.

The capacitor holes 91 and the dummy bottom electrode groove 91a can be formed by a photolithography process and a dry etching process. The capacitor holes 91 and the dummy bottom electrode groove 91a penetrate the inter-layer insulators 32, 24 and 36. The capacitor holes 91 reach the landing pads 81 in the memory cell area 100. Parts of the landing pads 81 are exposed to the capacitor holes 91 in the memory cell area 100. The dummy bottom electrode groove 91a reaches the base 81c in the boundary area 200. A part of the base 81c is exposed to the dummy bottom electrode groove 91a. In some cases, the capacitor holes 91 may have a circular shape in plan view. The dummy bottom electrode groove 91a may have a frame shape in plan view, so that the dummy bottom electrode groove 91a extends to surround the memory cell area 100.

The dummy bottom electrode groove 91a separates the inter-layer insulator 36 into a first portion which extends in the memory cell area 100 and a second portion which extends in the peripheral circuit/logic circuit area 300. The first and second portions of the inter-layer insulator 36 are separated by the dummy bottom electrode groove 91a. The first portion of the inter-layer insulator 36 will be called to as an inter-layer insulator 36. The second portion of the inter-layer insulator 36 will be called to as an inter-layer insulator 36a.

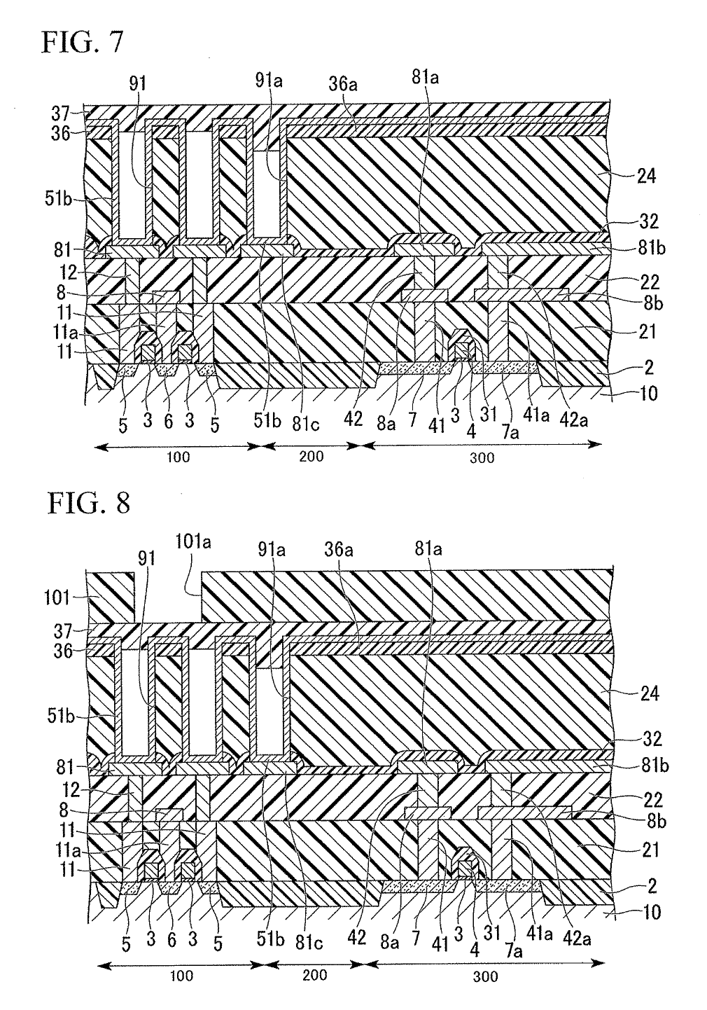

FIG. 7 is a fragmentary cross sectional elevation view illustrating a semiconductor device in a step subsequent to the step of FIG. 5, involved in the method of forming the semiconductor device of FIG. 1.

A conductive film 51b is formed in the memory cell area 100, the boundary area 200 and the peripheral circuit/logic circuit area 300. The conductive film 51b is formed entirely over the memory cell area 100, the boundary area 200 and the peripheral circuit/logic circuit area 300. The conductive film 51b extends along the inside walls of the capacitor holes 91 in the memory cell area 100. The conductive film 51b extends along the inside walls of the dummy bottom electrode groove 91a in the boundary area 200. The conductive film 51b extends on the exposed portions of the landing pads 81 in the memory cell area 100. The conductive film 51b extends on the exposed portion of the base 81c in the boundary area 200. The conductive film 51b extends over the inter-layer insulator 36 in the memory cell area 100. The conductive film 51b extends over the inter-layer insulator 36a in the peripheral circuit/logic circuit area 300. The conductive film 51b can be formed by, but not limited to, a chemical vapor deposition method.

The thickness of the conductive film 51b may preferably be thick enough to prevent an etchant from penetrating the conductive film 51b, wherein the etchant is used to wet-etch the inter-layer insulator 24. The conductive film 51b will be reduced in thickness in later processes. Increase in the thickness of the conductive film 51b makes it difficult to reduce the thickness of the conductive film 51b. Increase in the thickness of the conductive film 51b makes longer the necessary time for reducing the thickness of the conductive film 51b, thereby lowering the productivity. In some cases, the conductive film 51b may be made of, but is not limited to, titanium nitride. The inter-layer insulator 24 may be made of, but is not limited to, silicon oxide. The etchant used to wet-etch the inter-layer insulator 24 may be, but is not limited to, a diluted hydrogen fluoride. Under these conditions, the thickness of the conductive film 51b may be preferably be, but is not limited to, in the range of 18 nm to 25 nm, and more preferably be in the range of 20 nm to 24 nm.

An inter-layer insulator 37 is formed over the memory cell area 100, the boundary area 200 and the peripheral circuit/logic circuit area 300. The inter-layer insulator 37 extends over the conductive film 51b and fills shallower portions of the capacitor holes 91 in the memory cell area 100. The inter-layer insulator 37 extends over the conductive film 51b and fills a shallower portion of the dummy bottom electrode groove 91a in the boundary area 200. The inter-layer insulator 37 extends over the conductive film 51b in the peripheral circuit/logic circuit area 300. The capacitor holes 91 are filled with the inter-layer insulator 37 imperfectly. Only the shallower portions of the capacitor holes 91 are filled with the inter-layer insulator 37. The dummy bottom electrode groove 91a is filled with the inter-layer insulator 37 imperfectly. Only the shallower portion of the dummy bottom electrode groove 91a is filled with the inter-layer insulator 37. The inter-layer insulator 37 can be formed by, but is not limited to, a plasma chemical vapor deposition method.

The inter-layer insulator 37 performs as a stopper to prevent a resist film from going into the capacitor holes 91 and into the dummy bottom electrode groove 91a. The resist film is formed to selectively remove the inter-layer insulator 36 thereby forming beams of the inter-layer insulator 36. The beams of the inter-layer insulator 36 mechanically support the bottom electrodes 51 and the dummy bottom electrode 51a. Once the resist film enters the capacitor holes 91 and the dummy bottom electrode groove 91a, it is not easy to remove the resist film from the capacitor holes 91 and the dummy bottom electrode groove 91a.

The inter-layer insulator 37 also performs as a protector which prevents the conductive film 51b from being etched from the inside walls of the capacitor holes 91 and the inside walls of the dummy bottom electrode groove 91a when the inter-layer insulator 36 is selectively removed thereby forming beams of the inter-layer insulator 36.

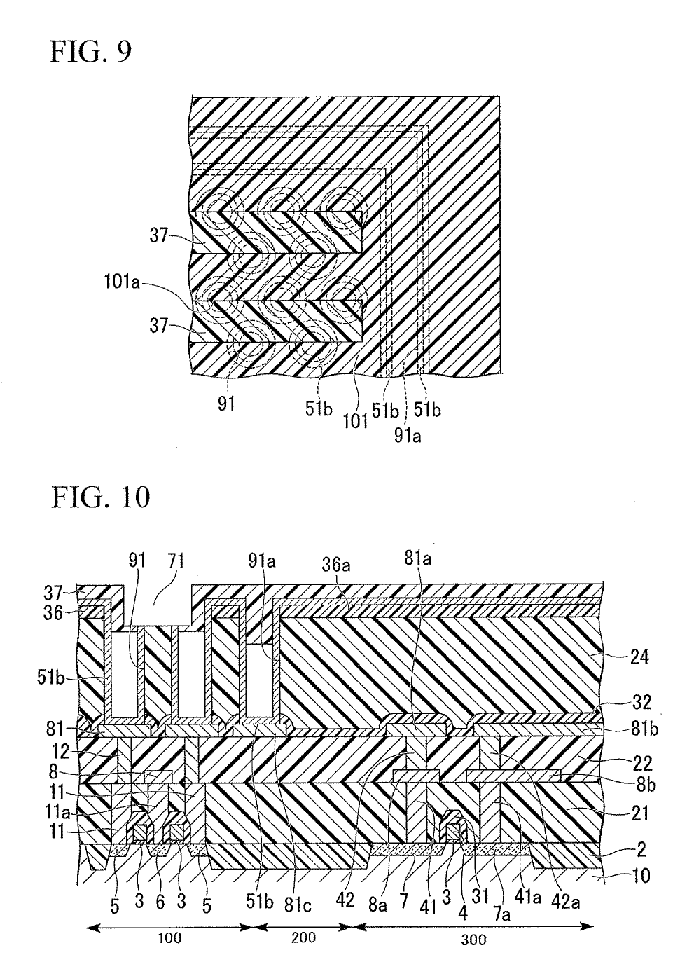

FIG. 8 is a fragmentary cross sectional elevation view illustrating a semiconductor device in a step subsequent to the step of FIG. 7, involved in the method of forming the semiconductor device of FIG. 1. FIG. 9 is a fragmentary plan view illustrating a memory cell area of the semiconductor device shown in FIG. 8.

A photo-resist pattern 101 is formed by a photolithograph process over the inter-layer insulator 37. The photo-resist pattern 101 extends over the memory cell area 100, the boundary area 200 and the peripheral circuit/logic circuit area 300. The photo-resist pattern 101 has an alignment of stripe-shaped openings 101a in the memory cell area 100.

FIG. 10 is a fragmentary cross sectional elevation view illustrating a semiconductor device in a step subsequent to the step of FIG. 8, involved in the method of forming the semiconductor device of FIG. 1.

The photo-resist pattern 101 is used as a mask to carry out a dry etching process to selectively etch the inter-layer insulators 37 and 36 and the conductive film 51b, thereby forming windows 71, and making the beams of the inter-layer insulator 36. The beams of the inter-layer insulator 36 mechanically support the bottom electrodes 51. The inter-layer insulator 36a in the peripheral circuit/logic circuit area 300 is not etched by this etching process.

The photo-resist pattern 101 is removed by a know method such as an ashing process.

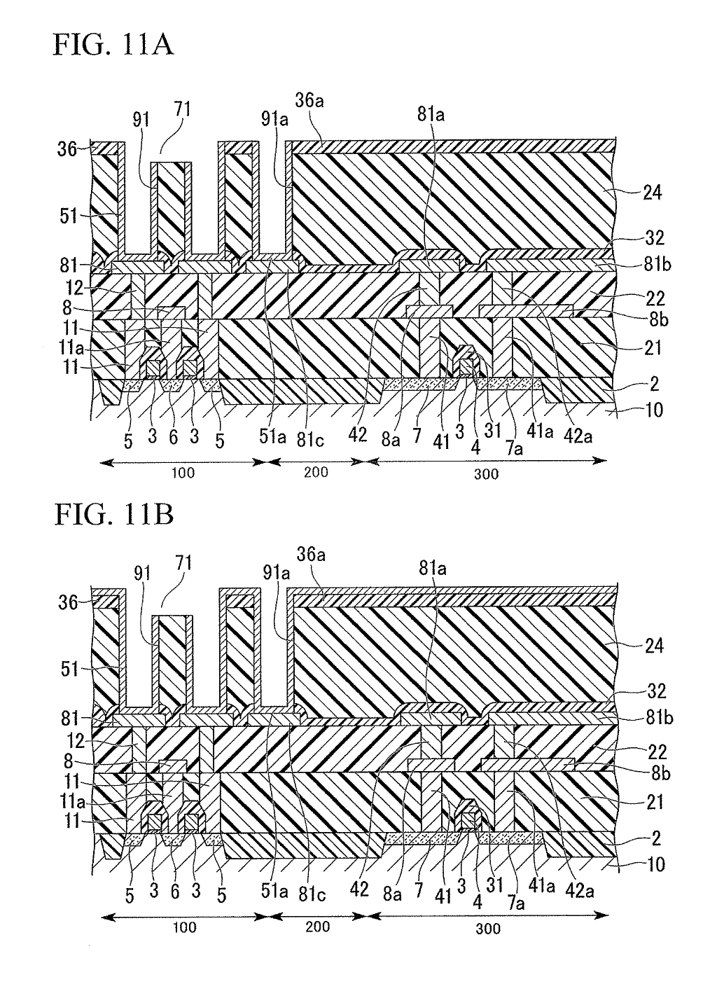

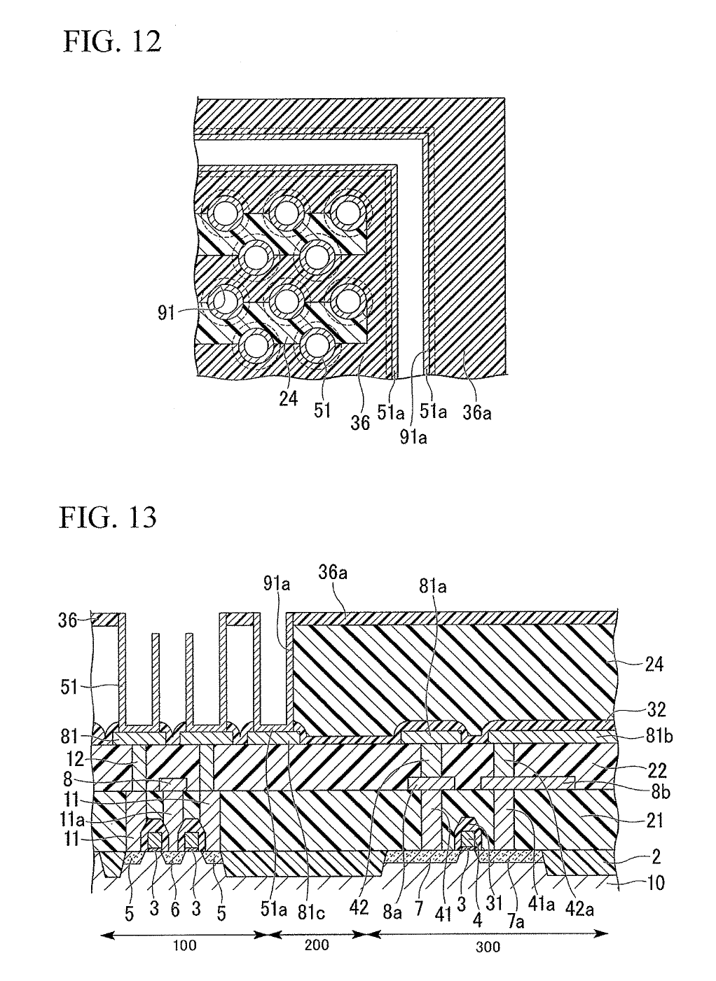

FIG. 11A is a fragmentary cross sectional elevation view illustrating a semiconductor device in a step subsequent to the step of FIG. 10, involved in the method of forming the semiconductor device of FIG. 1. FIG. 12 is a fragmentary plan view illustrating a memory cell area of the semiconductor device shown in FIG. 11A.

The inter-layer insulator 37 and the conductive film 51b are removed, except for the conductive film 51b which extends along the inside walls of the capacitor holes 91 and the dummy bottom electrode groove 91a so that the conductive film 51b remains only within the capacitor holes 91 and the dummy bottom electrode groove 91a. As a result, the remaining conductive films 51b in the capacitor holes 91 perform as the bottom electrodes 51, and the remaining conductive film 51b in the dummy bottom electrode groove 91a perform as the dummy bottom electrode 51a. Namely, the conductive film 51b and the dummy bottom electrode 51a are concurrently formed in the capacitor holes 91 and in the dummy bottom electrode 51a, respectively.

In some cases, the inter-layer insulator 37 may be, but is not limited to, a silicon nitride film formed by a plasma chemical vapor deposition. The inter-layer insulator 32 may be, but is not limited to, a silicon nitride film formed by a low pressure chemical vapor deposition process or an atomic layer deposition. The inter-layer insulator 36 may be, but is not limited to, a silicon nitride film formed by an atomic layer deposition at a growth temperature of 550° C. Under these conditions, the conductive film 51b is partially removed, except for the conductive film 51b which extends along the inside walls of the capacitor holes 91 and the dummy bottom electrode groove 91a so that the conductive film 51b remains only within the capacitor holes 91 and the dummy bottom electrode groove 91a. Even if the inter-layer insulator 37 may partially reside in the shallower portions of the capacitor holes 91 and the dummy bottom electrode groove 91a, the residual inter-layer insulator 37 in the shallower portions of the capacitor holes 91 and the dummy bottom electrode groove 91a can be removed by the wet etching process using the diluted hydrogen fluoride to remove the inter-layer insulator 24. FIGS. 11A and 12 show that the inter-layer insulator 37 is perfectly removed.

The inter-layer insulator 37 is a silicon nitride film formed by a plasma chemical vapor deposition. The inter-layer insulator 32 is a silicon nitride film formed by a low pressure chemical vapor deposition process or an atomic layer deposition. The inter-layer insulator 36 is a silicon nitride film formed by an atomic layer deposition at a growth temperature of 550° C. The inter-layer insulator 32 has an etching rate of 1.3 nm/sec. to the diluted hydrogen fluoride etchant. The inter-layer insulator 36 has an etching rate of 0.58 nm/sec. to the diluted hydrogen fluoride etchant. The inter-layer insulator 37 has an etching rate of about 5 nm/sec. to the diluted hydrogen fluoride etchant. These allow that the wet etching process for wet-etching the inter-layer insulator 24 further etches the inter-layer insulator 37, while leaving the inter-layer insulators 32 and 36.

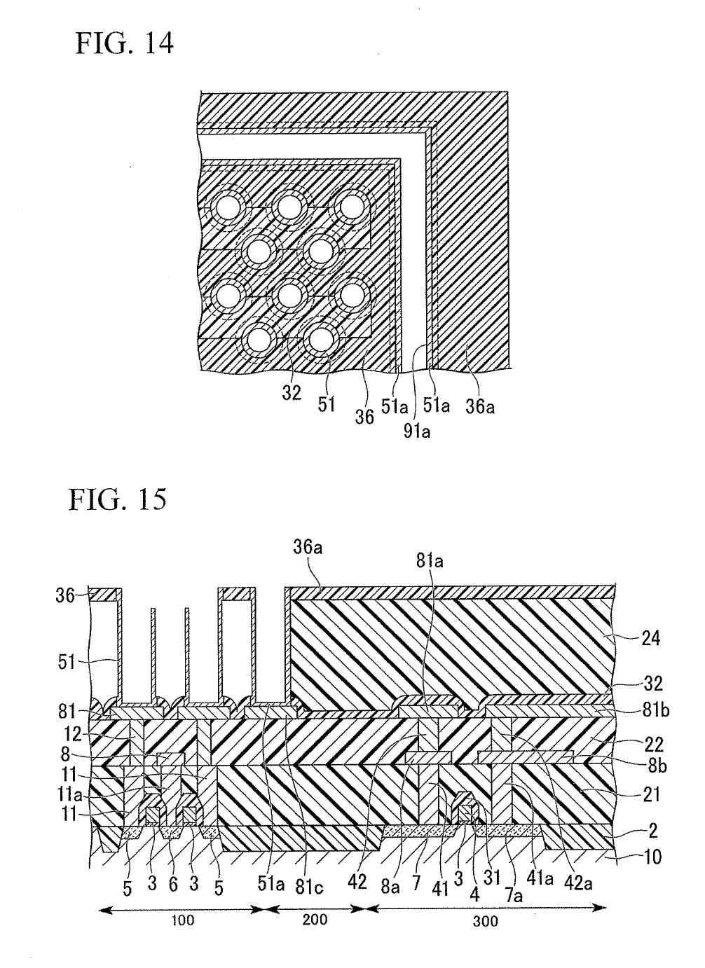

FIG. 13 is a fragmentary cross sectional elevation view illustrating a semiconductor device in a step subsequent to the step of FIG. 11A, involved in the method of forming the semiconductor device of FIG. 1. FIG. 14 is a fragmentary plan view illustrating a memory cell area of the semiconductor device shown in FIG. 13.

A wet etching process is carried out using the dummy bottom electrode 51a and the inter-layer insulators 32, 36 and 36a as etching stoppers, to etch the inter-layer insulator 24 in the memory cell area 100. Namely, the inter-layer insulator 24 surrounded by the dummy bottom electrode 51a is wet-etched by using the dummy bottom electrode 51a and the inter-layer insulators 32, 36 and 36a as etching stoppers. If the conductive film 51b as the dummy bottom electrode 51a is a titanium nitride film and the inter-layer insulator 24 is a silicon oxide film, the etchant may preferably be a diluted hydrogen fluoride.

The wet etching is an isotropic etching. Thus, the inter-layer insulator 24 under the inter-layer insulator 36 in the memory cell area 100 is completely removed. The inter-layer insulator 36 remains and performs as the beams which mechanically support the bottom electrodes 51 and the dummy bottom electrode 51a. In the peripheral circuit/logic circuit area 300, the inter-layer insulator 24 is not etched while the inter-layer insulator 24 is protected by the inter-layer insulator 36a and the dummy bottom electrode 51a. In the memory cell area 100, the bottom electrodes 51 are mechanically supported by the beams of the inter-layer insulator 36. The beams of the inter-layer insulator 36 mechanically connect the upper portions of the bottom electrodes 51, so that the beams of the inter-layer insulator 36 prevent that the bottom electrodes 51 from contacting each other and from falling down. The bottom electrodes 51 are mechanically inter-connected to each other via the mechanical supporters of the beams of the inter-layer insulator 36.

The dummy bottom electrode 51a may perform a guard ring which prevents the etchant from penetrating the wall of the dummy bottom electrode 51a to the inter-layer insulator 24 which is positioned under the inter-layer insulator 36a. The guard ring of the dummy bottom electrode 51a prevents the etchant from penetrating the wall of the dummy bottom electrode 51a and from reaching the inter-layer insulator 24 in the peripheral circuit/logic circuit area 300.

The inter-layer insulator 32 may perform as a stopper which prevents the etchant from perpetrating the inter-layer insulator 32 and reaching the inter-layer insulator 22. The inter-layer insulator 22 is disposed under the inter-layer insulator 32. The etchant is used to etch the inter-layer insulator 24. The inter-layer insulators 24 and 22 may be made of, but are not limited to, the same material such as silicon oxide. In this case, if the etchant for etching the inter-layer insulator 24 contacts the inter-layer insulator 22, then the etchant will etches the inter-layer insulator 22, thereby the semiconductor device being defect, and lowering the yield of the semiconductor device.

FIG. 15 is a fragmentary cross sectional elevation view illustrating a semiconductor device in a step subsequent to the step of FIG. 13, involved in the method of forming the semiconductor device of FIG. 1.

The thickness of the conductive films 51b is reduced. The conductive films 51b perform as the bottom electrodes 51 and as the dummy bottom electrode 51a. The reduction in the thickness of the bottom electrodes 51 and the dummy bottom electrode 51a can be realized by any available method such as a wet etching process and a dry etching process. In order to reduce the number of processes, the bottom electrodes 51 and the dummy bottom electrode 51a may be concurrently reduced in thickness by the same thickness reduction process. It is also possible that only the bottom electrodes 51 may be subjected to the thickness reduction process, while the dummy bottom electrode 51a is not reduced in thickness. Namely, at least the bottom electrodes 51 may preferably be subjected to the thickness reduction process.

Reduction in the thickness of the bottom electrodes 51 will allow increasing the inside dimension of the thickness-reduced bottom electrodes 51. The inside dimension of the bottom electrode 51 is defined between inside walls of the bottom electrode 51 in a horizontal direction parallel to the surface of the substrate 10. When the bottom electrode 51 has a cylindrical shape, the inside dimension of the bottom electrode 51 is an inner diameter of the cylinder of the bottom electrode 51. Increase in the inside dimension of the thickness-reduced bottom electrodes 51 makes it easy to form at good coverage the capacitive insulating film 52 and the top electrode 53 in the inside space of the bottom electrodes 51. Increasing the inside dimension of the bottom electrodes 51 may improve the coverage of the capacitive insulating film 52 and the top electrode 53. In case that the bottom electrodes 51 have a cylinder shape, increasing the inner diameter of the bottom electrodes 51 makes it easy to form at good coverage the capacitive insulating film 52 and the top electrode 53 in the inside space of the bottom electrodes 51. Increasing the inner diameter of the bottom electrodes 51 may improve the coverage of the capacitive insulating film 52 and the top electrode 53. Improvement in the coverage of the capacitive insulating film 52 and the top electrode 53 may suppress or reduce the leakage of current inside the bottom electrodes 51. In these viewpoints, the thickness of the bottom electrodes 51 may preferably be, but is not limited to, less than 18 nm. Reducing the thickness of the bottom electrodes 51 reduces its mechanical strength or rigidity. Reducing the thickness of the bottom electrodes 51 makes the bottom electrodes 51 likely to be deformed or falling down. In view of providing the bottom electrodes 51 with the mechanical strength or rigidity, the thickness of the bottom electrodes 51 may preferably be, but is not limited to, at least 8 nm. In views of both ensuring the sufficient inside dimension of the bottom electrodes 51 and ensuring the mechanical strength or rigidity, the thickness of the bottom electrodes 51 may preferably be, but is not limited to, in the range of 8 nm to less than 18 nm, and more preferably in the range of 14 nm to 15 nm.

The inside diameter of the bottom electrodes 51 should be larger than the sum of the double of the thicknesses of the capacitive insulating film 52 and the thickness of the top electrode 53. Increasing the inside diameter of the bottom electrodes 51 is preferable in view of ensuring good coverage of the capacitive insulating film 52 and the top electrode 53. When the bottom electrodes 51 have a cylinder shape, the inner diameter of the bottom electrodes 51 should be larger than the sum of the double of the thicknesses of the capacitive insulating film 52 and the thickness of the top electrode 53. In view of ensuring good coverage of the capacitive insulating film 52 and the top electrode 53, the inside dimension or the inside diameter of the bottom electrodes 51 may preferably be, but is not limited to, at least 15 nm and more preferably at least 20 nm.

As described above, the bottom electrodes 51 and the dummy bottom electrode 51a can be reduced in thickness by either the dry etching process or the wet etching process. The wet etching process will be described. If the bottom electrodes 51 and the dummy bottom electrode 51a are made of titanium nitride, and the wet etching process is used to reduce the thickness of the bottom electrodes 51 and the dummy bottom electrode 51a, a commercially available etchant can be used, for example, N-311 which is available from Nagase ChemteX Corporation. The etchant N-311 mainly contains hydroxylamine, 2-aminoethanol (alkanolamines), and dimethyl sulfoxide. Hydroxylamine and 2-aminoethanol dissolve titanium nitride. The bottom electrodes 51 and the dummy bottom electrode 51a made of titanium nitride can be reduced in thickness by about 3 nm by the wet etching process using N-311 for about 20 min.

As described above, the bottom electrodes 51 and the dummy bottom electrode 51a can be reduced in thickness by the dry etching process. If the bottom electrodes 51 and the dummy bottom electrode 51a are made of titanium nitride, any available etching system can be used to reduce the thickness of the bottom electrodes 51 and the dummy bottom electrode 51a. There can be used an ICP plasma etching system which introduce a down-flow of plasma to a semiconductor wafer. An etching gas may be, but is not limited to, a mixture gas of chlorine (Cl₂) and argon (Ar), another mixture gas of chlorine (Cl₂) and nitrogen (N₂), or still another mixture gas of chlorine (Cl₂) and oxygen (O₂). Chlorine (Cl₂) and argon (Ar) may be introduced at flow rates of 1 sccm and 10 sccm, respectively into the etching system. Chlorine (Cl₂) and nitrogen (N₂) may be introduced at flow rates of 1 sccm and 10 sccm, respectively into the etching system. Chlorine (Cl₂) and oxygen (O₂) may be introduced at flow rates of 1 sccm and 10 sccm, respectively into the etching system. The pressure of the inside of an etching chamber of the system is maintained in the range of 1 mTorr to 10 mTorr. The temperature of the inside of the etching chamber of the system is maintained in the range of 20° C. to 30° C. A radio frequency power in the range of 1000 W to 2000 W is applied to the etching chamber.

The bottom electrodes 51 and the dummy bottom electrode 51a are subjected to the etching process for reducing the thickness thereof, except for those contact portions which contact at least one of the landing pads 81, the base 81c and the interlayer insulators 24, 32 and 36 as shown in FIG. 15. The bottom electrode 51 has an upper portion which contacts the inter-layer insulator 36. The upper portion of the bottom electrode 51 is not etched and not reduced in thickness. The bottom electrode 51 has a lower portion which contacts the inter-layer insulator 32. The lower portion of the bottom electrode 51 is not etched and not reduced in thickness. The bottom electrode 51 has a bottom portion which contacts the landing pad 81. The bottom portion of the bottom electrode 51 is not etched and not reduced in thickness. Namely, the bottom electrode 51 is etched and reduced in thickness except for the upper portion which contacts the inter-layer insulator 36, except for the lower portion which contacts the inter-layer insulator 32, and except for the bottom portion which contacts the landing pad 81.

The dummy bottom electrode 51a includes an inside wall, an outside wall and a bottom wall. The inside and outside walls of the dummy bottom electrode 51a extend upwardly. The inside wall of the dummy bottom electrode 51a includes a first portion and a second portion. The first portion of the inside wall contacts the inter-layer insulators 36 and 32. The second portion of the inside wall do not contact the inter-layer insulators 36 and 32. The second portion of the inside wall is thinner than the first portion of the inside wall. The first portion is thicker than the second portion. The bottom wall is thicker than the second portion. The outside wall of the dummy bottom electrode 51a contacts the inter-layer insulators 32, 24 and 36. The outside wall and the inside wall have inside faces which face toward each other. The outside wall of the dummy bottom electrode 51a is thickener than the second portion of the inside wall. The outside wall of the dummy bottom electrode 51a is as thick as the first portion of the inside wall and the bottom wall. The first portion of the inside wall includes an upper portion which contacts the inter-layer insulator 36, and a lower portion which contacts the inter-layer insulator 32.

The second portion of the inside wall of the dummy bottom electrode 51a is etched and reduced in thickness, while the first portion of the inside wall of the dummy bottom electrode 51a is not etched and not reduced in thickness since the first portion contacts the inter-layer insulators 32 and 36. The bottom wall of the dummy bottom electrode 51a is not etched and not reduced in thickness since the bottom wall contacts the base 81c. The outside wall of the dummy bottom electrode 51a is not etched and not reduced in thickness since the outside wall contacts the inter-layer insulators 32, 24 and 36.

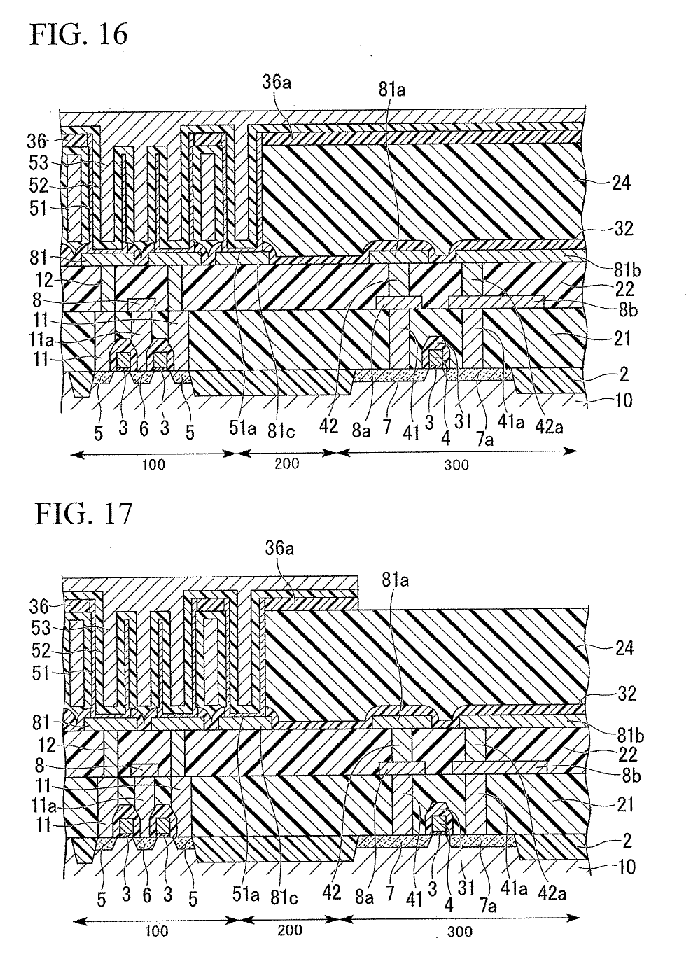

FIG. 16 is a fragmentary cross sectional elevation view illustrating a semiconductor device in a step subsequent to the step of FIG. 15, involved in the method of forming the semiconductor device of FIG. 1.

A capacitive insulating film 52 is formed which covers the bottom electrodes 51, the dummy bottom electrode 51a and the inter-layer insulator 36. The capacitive insulating film 52 extends over the memory cell area 100, the boundary area 200 and the peripheral circuit/logic circuit area 300. The capacitive insulating film 52 may have a multi-layered structure of dielectric or insulator. In some cases, the capacitive insulating film 52 may include, but is not limited to, an aluminum oxide film and a zirconium oxide film. The thickness of the capacitive insulating film 52 may be, but is not limited to, in the range of about 6 nm to about 7 nm. The aluminum oxide film and the zirconium oxide film may be formed by atomic layer deposition method.

A top electrode layer 53 is formed which covers the capacitive insulating film 52, so that the top electrode layer 53 fills up the capacitive holes 91 and the dummy bottom electrode groove 91a. The top electrode layer 53 extends over the memory cell area 100, the boundary area 200 and the peripheral circuit/logic circuit area 300. The top electrode layer 53 may be made of, but is not limited to, titanium nitride. The thickness of the top electrode layer 53 may be, but is not limited to, about 8 nm. The top electrode layer 53 can be formed by a chemical vapor deposition method. The top electrode layer 53 within the capacitor holes 91 has a vertical dimension in a vertical direction and a horizontal dimension in a horizontal direction. Of the top electrode layer 53 within the capacitor holes 91, the vertical dimension is greater than the horizontal dimension. The vertical direction is a direction vertical to the main surface of the semiconductor substrate 10. The vertical direction is parallel to a depth direction in which the depth of the capacitor holes 91 and the dummy bottom electrode grove 91a is defined. The horizontal direction is a direction parallel to the main surface of the semiconductor substrate 10. The horizontal direction is perpendicular to the vertical direction. In some cases, the top electrode layer 53 within the capacitor holes 91 may have, but is not limited to, a vertical dimension of 8 nm and a horizontal dimension of 5 nm.

In some cases, the top electrode 53 may have a single-layered film. The top electrode 53 may have a multi-layered film. The multi-layered film may include, but is not limited to, a titanium nitride film, a poly-SiGe film, and a tungsten film. The titanium nitride film contacts the capacitive insulating film 52. The poly-SiGe film contacts the titanium nitride film. The tungsten film contacts the poly-SiGe film. The titanium nitride film can be formed by a chemical vapor deposition method. The thickness of the titanium nitride film may be, but is not limited to, about 8 nm. The poly-SiGe film may be doped with boron (B). The poly-SiGe film can be formed by a chemical vapor deposition method. The thickness of the poly-SiGe film may be, but is not limited to, about 130 nm. The tungsten film can be formed by a sputtering process. The thickness of the tungsten film may be, but is not limited to, about 100 nm. The titanium nitride film can mainly perform as a top electrode. The poly-SiGe film can mainly perform as a filler which fills a gap between the bottom electrodes 51 and other gap between the bottom electrodes 51 and the dummy bottom electrode 51a. The poly-SiGe film performing as the filler can prevent the capacitor from being deformed during later processes. The deformation of the capacitor may cause leakage of current. The poly-SiGe film performing as the filler can prevent any formation of a spatial gap which will cause cracking. The tungsten film may reduce the resistance of the top electrode 51, thereby reducing electric noise when any charge as a piece of information stored in the capacitor is red out.

FIG. 17 is a fragmentary cross sectional elevation view illustrating a semiconductor device in a step subsequent to the step of FIG. 16, involved in the method of forming the semiconductor device of FIG. 1.

In the boundary area 200 and the peripheral circuit/logic circuit area 300, there are a multi-layered structure which includes the inter-layer insulator 36a, the capacitive insulating film 52 and the top electrode layer 53. The multi-layered structure extends over the inter-layer insulator 24. In the peripheral circuit/logic circuit area 300, the multi-layered structure is selectively removed by a photo-lithography technique and a dry etching process, so that the inter-layer insulator 24 is exposed. The inter-layer insulator 36a, the capacitive insulating film 52 and the top electrode layer 53 remain in the boundary area 200. The inter-layer insulator 36, the capacitive insulating film 52 and the top electrode layer 53 remain in the memory cell area 100. As a result, the capacitors are defined in the memory cell area 100. Each capacitor includes the bottom electrode 51, the capacitive insulating film 52 and the top electrode layer 53. The capacitor may have a height of about 1.5 micrometers. The capacitor may have a crown-shape.

In view of making it easier to form the contact holes for the contact plugs 43 and 43a in the peripheral circuit/logic circuit area 300, the inter-layer insulator 36a is removed in addition to the capacitive insulating film 52 and the top electrode layer 53 in the peripheral circuit/logic circuit area 300.

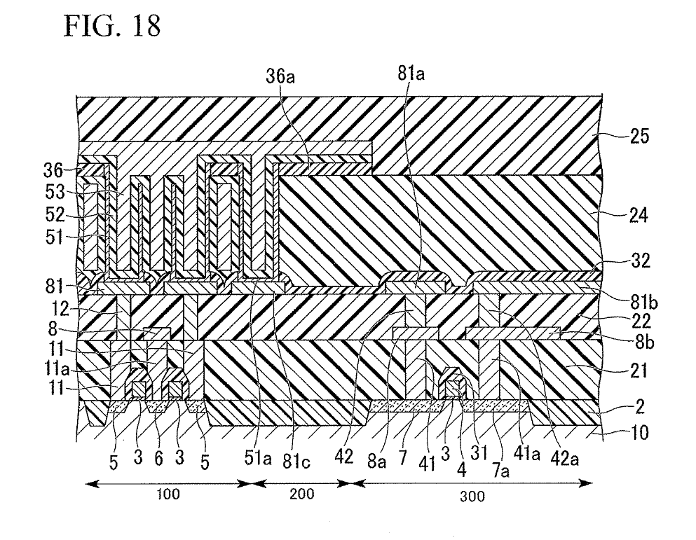

FIG. 18 is a fragmentary cross sectional elevation view illustrating a semiconductor device in a step subsequent to the step of FIG. 17, involved in the method of forming the semiconductor device of FIG. 1.

An inter-layer insulator 25 is formed over the top electrode layer 53 in the memory cell area 100 and the boundary area 200, and also over the inter-layer insulator 24 in the peripheral circuit/logic circuit area 300. The inter-layer insulator 25 extends over the top electrode layer 53 and the inter-layer insulator 24. The top surface of the top electrode layer 53 is higher than the top surface of the inter-layer insulator 24. The inter-layer insulator 25 has a difference in level between the boundary area 200 and the peripheral circuit/logic circuit area 300. The inter-layer insulator 25 may be made of, but is not limited to, silicon oxide. The inter-layer insulator 25 is then planarized by a chemical mechanical polishing process. The inter-layer insulator 25 has a planarized surface. The inter-layer insulator 25 may be made of other insulating material than silicon oxide. In view of making it easier to form contact holes for the contact plugs 43 and 43a in the peripheral circuit/logic circuit area 300, it is preferable that the inter-layer insulator 25 is made of the same insulating material as the inter-layer insulator 24.

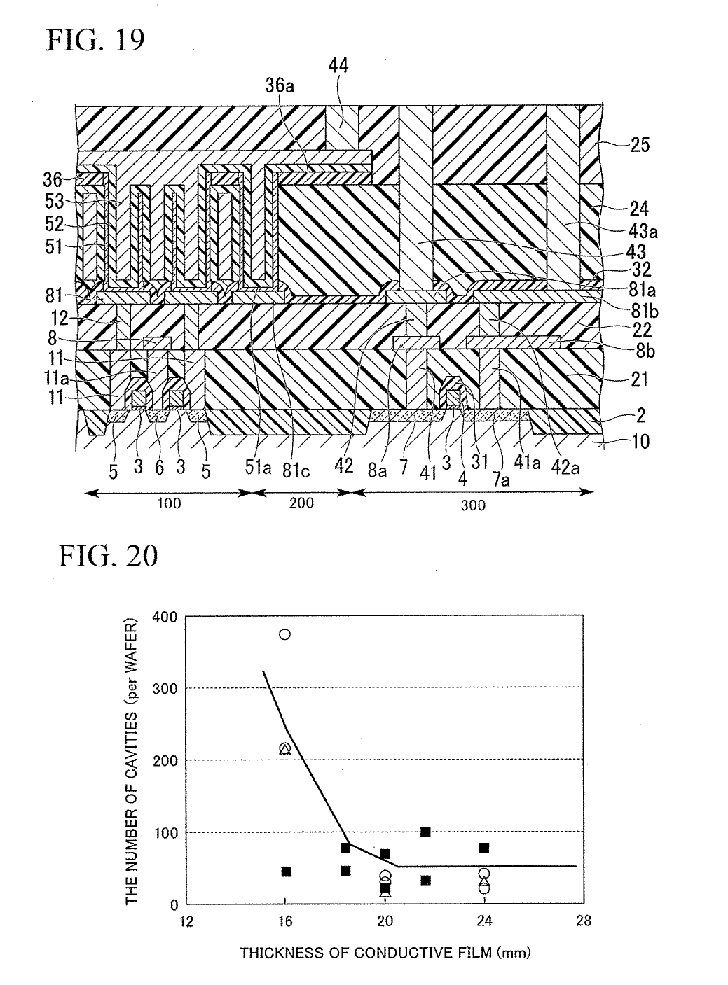

FIG. 19 is a fragmentary cross sectional elevation view illustrating a semiconductor device in a step subsequent to the step of FIG. 18, involved in the method of forming the semiconductor device of FIG. 1.

First, second and third contact holes are formed in the boundary area 200 and the peripheral circuit/logic circuit area 300. The first contact hole is formed in the boundary area 200. The first contact hole penetrates the inter-layer insulator 25 in the boundary area 200 so that the first contact hole reaches the top electrode 53 in the boundary area 200. The second contact hole is formed in the peripheral circuit/logic circuit area 300. The second contact hole penetrates the inter-layer insulators 25, 24 and 32 in the peripheral circuit/logic circuit area 300 so that the second contact hole reaches the local wiring 81a in the peripheral circuit/logic circuit area 300. The third contact hole is formed in the peripheral circuit/logic circuit area 300. The third contact hole penetrates the inter-layer insulators 25, 24 and 32 in the peripheral circuit/logic circuit area 300 so that the third contact hole reaches the local wiring 81b in the peripheral circuit/logic circuit area 300. A part of the top electrode 53 is exposed to the first contact hole. A part of the local wiring 81a is exposed to the second contact hole. A part of the local wiring 81b is exposed to the third contact hole.

A conductive film is formed which fills up the first, second and third contact holes and extends over the inter-layer insulator 25. In some cases, the conductive film may have a single-layered film. In other cases, the conductive film may have a multi-layered film. The multi-layered film may be, but is not limited to, a titanium nitride film and a tungsten film. The conductive film reaches the exposed part of the top electrode 53, the exposed part of the local wiring 81a, and the exposed part of the local wiring 81b. The conductive film contacts the top electrode 53, the local wiring 81a, and the local wiring 81b. The conductive film is removed except in the first, second and third contact holes, thereby forming contact plugs 44, 43 and 43a in the first, second and third contact holes, respectively. The contact plug 44 contacts the top electrode 53. The contact plug 43 contacts the local wiring 81a. The contact plug 43a contacts the local wiring 81b. The conductive film over the inter-layer insulator 25 can be removed by a chemical mechanical polishing process, while leaving the conductive film in the first, second and third contact holes.

With reference again to FIG. 1, a conductive film is formed over the contact plugs 43, 43a and 44, and the inter-layer insulator 25. In some cases, the conductive film may have a single-layered film. In other cases, the conductive film may have a multi-layered film. The multi-layered film may be, but is not limited to, a titanium film, an aluminum film, and a titanium nitride film. The titanium film contacts the contact plugs 43, 43a and 44, and the inter-layer insulator 25. The aluminum film contacts the titanium film. The titanium film contacts the aluminum film. The conductive film is then patterned to form second level wirings 61 and 61a. The conductive film can be patterned by a lithography technique and a dry etching process.

The second level wiring 61 runs over the inter-layer insulator 25. The second level wiring 61 contacts the contact plug 44. The second level wiring 61 is electrically connected through the contact plug 44 to the top electrode 53. The second level wiring 61 contacts the contact plug 43. The second level wiring 61 is electrically connected through the contact plug 43a, the local wiring 81b, the contact plug 42a, the first level writing 8b, and the contact plug 41a to the diffusion region 7a. The second level wiring 61 electrically connects the contact plug 44 and the contact plug 43. Thus, the top electrode 53 of the capacitors is eclectically connected through the contact plug 44, the second level wiring 61, the contact plug 43a, the local wiring 81b, the contact plug 42a, the first level writing 8b, and the contact plug 41a to the diffusion region 7a. In the memory cell area 100, the transistors are connected to the capacitors. The capacitors in the memory cell area 100 are electrically connected to the transistor in the peripheral circuit/logic circuit area 300.

The second level wiring 61a runs over the inter-layer insulator 24. The second level wiring 61a contacts the contact plug 43a. The second level wiring 61a is electrically connected through the contact plug 43a, the local wiring 81b, the contact plug 42a, the first level writing 8b and the contact plug 41a to the diffusion region 7a.

In accordance with the above-described embodiment, the capacitor holes 91 and the dummy bottom electrode groove 91a are formed in the inter-layer insulator 24. The conductive films 51b are formed in the capacitor holes 91 and in the dummy bottom electrode groove 91a. The wet etching process is carried by using the conductive films 51b as etching stoppers to remove the inter-layer insulator 24 in the memory cell area 100 and in the dummy bottom electrode groove 91a, without etching the inter-layer insulator 24 outside the dummy bottom electrode groove 91a. In the wet etching process, the conductive film 51b has the outside wall which contacts the inter-layer insulator 24, and the outside wall have a thickness which is thick enough to prevent the etchant from penetrating the outside wall and reaching the inter-layer insulator 24 which is positioned outside the dummy bottom electrode groove 91a. As a result, thereby is formed no cavity in the inter-layer insulator 24 outside the dummy bottom electrode groove 91a. No cavity formation ensures no short circuit formation between the dummy bottom electrode 51a in the dummy bottom electrode groove 91a and the contact plug 43.

In accordance with the above-described embodiment, the thickness of the conductive films 51b is reduced. The bottom electrodes 51 and the dummy bottom electrode 51a are subjected to the etching process for reducing the thickness thereof, except for those contact portions which contact at least one of the landing pads 81, the base 81c and the interlayer insulators 24, 32 and 36 as shown in FIG. 15. The bottom electrode 51 has the upper portion which contacts the inter-layer insulator 36. The upper portion of the bottom electrode 51 is not etched and not reduced in thickness. The bottom electrode 51 has the lower portion which contacts the inter-layer insulator 32. The lower portion of the bottom electrode 51 is not etched and not reduced in thickness. The bottom electrode 51 has the bottom portion which contacts the landing pad 81. The bottom portion of the bottom electrode 51 is not etched and not reduced in thickness. Namely, the bottom electrode 51 is etched and reduced in thickness except for the upper portion which contacts the inter-layer insulator 36, except for the lower portion which contacts the inter-layer insulator 32, and except for the bottom portion which contacts the landing pad 81.

The dummy bottom electrode 51a includes the inside wall, the outside wall and the bottom wall. The first portion of the inside wall contacts the inter-layer insulators 36 and 32. The second portion of the inside wall do not contact the inter-layer insulators 36 and 32. The second portion of the inside wall is thinner than the first portion of the inside wall. The first portion is thicker than the second portion. The bottom wall is thicker than the second portion. The outside wall of the dummy bottom electrode 51a contacts the inter-layer insulators 32, 24 and 36. The outside wall of the dummy bottom electrode 51a is thickener than the second portion of the inside wall. The outside wall of the dummy bottom electrode 51a is as thick as the first portion of the inside wall and the bottom wall. The first portion of the inside wall includes the upper portion which contacts the inter-layer insulator 36, and the lower portion which contacts the inter-layer insulator 32.

The second portion of the inside wall of the dummy bottom electrode 51a is etched and reduced in thickness, while the first portion of the inside wall of the dummy bottom electrode 51a is not etched and not reduced in thickness since the first portion contacts the inter-layer insulators 32 and 36. The bottom wall of the dummy bottom electrode 51a is not etched and not reduced in thickness since the bottom wall contacts the base 81c. The outside wall of the dummy bottom electrode 51a is not etched and not reduced in thickness since the outside wall contacts the inter-layer insulators 32, 24 and 36.

Reduction in the thickness of the bottom electrodes 51 will allow increasing the inside dimension of the thickness-reduced bottom electrodes 51. Increase in the inside dimension of the thickness-reduced bottom electrodes 51 makes it easy to form at good coverage the capacitive insulating film 52 and the top electrode 53 in the inside space of the bottom electrodes 51. Increasing the inside dimension of the bottom electrodes 51 may improve the coverage of the capacitive insulating film 52 and the top electrode 53. Improvement in the coverage of the capacitive insulating film 52 and the top electrode 53 may suppress or reduce the leakage of current inside the bottom electrodes 51.

In accordance with the above-described embodiment, the landing pads 81, the local wirings 81a and 81b, and the base 81c are formed concurrently by the same processes which include a single lithography process and a single thy etching process. The bottom electrodes 51 and the dummy bottom electrode 51a are formed concurrently by the same processes which include a single lithography process and a single dry etching process. The inter-layer insulator 36 performing as the beams that mechanically support the bottom electrodes 51 and the dummy bottom electrode 51a is formed concurrently with the inter-layer insulator 36a by the same processes which include a single lithography process and a single dry etching process. These processes will cause no difference in level between the boundary area 220 and the peripheral circuit/logic circuit area 300. There is no need to any additional process for planarize the difference in level between the boundary area 220 and the peripheral circuit/logic circuit area 300.

In accordance with the above-described embodiment, the dummy bottom electrode 51a is provided in the boundary area 200. The dummy bottom electrode 51a surrounds the memory cell area in which the bottom electrodes 51 of the capacitors are provided. The inter-layer insulator 24 resides outside the dummy bottom electrode 51a. The inter-layer insulator 24 extends in the peripheral circuit/logic circuit area 300. The dummy bottom electrode 51a and the inter-layer insulator 24 allow that the formation of the capacitors in the memory cell area 100 results in substantially no difference in level between the memory cell area 100 and the peripheral circuit/logic circuit area 300. There is no need to reduce the difference in level between the memory cell area 100 and the peripheral circuit/logic circuit area 300. This will allow narrowing the boundary area 200 as compared to when the dummy bottom electrode 51a is not provided.

There is no need to increase the width of the boundary area 200 for reducing the difference in level between the memory cell area 100 and the peripheral circuit/logic circuit area 300. Thus, the second level wiring 61 can be provided without increasing the area of a semiconductor chip, wherein the second level wiring 61 is electrically connected through the contact plugs 44 and 43 to the top electrode 53 in the memory cell area 100 and the local wiring 81a in the peripheral circuit/logic circuit area 300.

It is possible to modify the above-described processes.

As shown in FIG. 10, the photo-resist pattern 101 is used as a mask to carry out a dry etching process to selectively etch the inter-layer insulators 37 and 36 and the conductive film 51b, thereby forming windows 71, and making the beams of the inter-layer insulator 36. The beams of the inter-layer insulator 36 mechanically support the bottom electrodes 51. The inter-layer insulator 36a in the peripheral circuit/logic circuit area 300 is not etched by this etching process.

The photo-resist pattern 101 is removed by a know method such as an ashing process.

FIG. 11B is a fragmentary cross sectional elevation view illustrating a semiconductor device in a modified step subsequent to the step of FIG. 10, involved in the modified method of forming the semiconductor device of FIG. 1.

The inter-layer insulator 37 is removed by a dry etching process. The inter-layer insulator 37 may be removed by the same etching process for etching the inter-layer insulator if the inter-layer insulator 37 is a silicon nitride film which is formed by a plasma chemical vapor deposition, the inter-layer insulator 32 is a silicon nitride film formed by a low pressure chemical vapor deposition method or an atomic layer deposition method, and the inter-layer insulator 36 is a silicon nitride film formed by an atomic layer deposition method at a growth temperature of 550° C.

By the same processes as described above, the wet etching process is carried out using the dummy bottom electrode 51b and the inter-layer insulators 32, 36 and 36a as etching stoppers, to etch the inter-layer insulator 24 in the memory cell area 100. Namely, the inter-layer insulator 24 surrounded by the dummy bottom electrode 51a is wet-etched by using the dummy bottom electrode 51b and the inter-layer insulators 32, 36 and 36a as etching stoppers.

The dummy bottom electrode 51b may perform a guard ring which prevents the etchant from penetrating the wall of the dummy bottom electrode 51a to the inter-layer insulator 24 which is positioned under the inter-layer insulator 36a. The guard ring of the dummy bottom electrode 51b prevents the etchant from penetrating the wall of the dummy bottom electrode 51b and from reaching the inter-layer insulator 24 in the peripheral circuit/logic circuit area 300.

Under these conditions, the conductive film 51b is partially removed, except for the conductive film 51b which extends along the inside walls of the capacitor holes 91 and the dummy bottom electrode groove 91a so that the conductive film 51b remains only within the capacitor holes 91 and the dummy bottom electrode groove 91a.

The thickness of the conductive films 51b is reduced. The conductive films 51b perform as the bottom electrodes 51 and as the dummy bottom electrode 51a. The reduction in the thickness of the bottom electrodes 51 and the dummy bottom electrode 51a can be realized by any available method such as a wet etching process and a dry etching process. In order to reduce the number of processes, the bottom electrodes 51 and the dummy bottom electrode 51a may be concurrently reduced in thickness by the same thickness reduction process. It is also possible that only the bottom electrodes 51 may be subjected to the thickness reduction process, while the dummy bottom electrode 51a is not reduced in thickness. Namely, at least the bottom electrodes 51 may preferably be subjected to the thickness reduction process.

### Example 1

The semiconductor devices shown in FIG. 1 were formed by the following processes. The number of the cavity in the inter-layer insulator 24 that is positioned outside the dummy bottom electrode groove 91a was investigated.

A silicon substrate 10 was prepared. Isolation films 2 were selectively formed on the main surface of the semiconductor substrate 10. The isolation films 2 define active regions in the memory cell area 100 and the peripheral circuit/logic circuit area 300. The isolation films 2 also define the memory cell area 100, the boundary area 200, and the peripheral circuit/logic circuit area 300.

Gate insulating films 3 were formed on the main surfaces of the active regions in the memory cell area 100 and the peripheral circuit/logic circuit area 300 in the same process. Gate electrodes 4 were formed on the gate insulating films 3 of the memory cell area 100 and the peripheral circuit/logic circuit area 300 in the same process. Diffusion regions 5 and 6 and diffusion regions 7 and 7a were formed in the active regions of the memory cell area 100 and the peripheral circuit/logic circuit area 300 in the same process. The diffusion regions 5 and 6 were formed in the active region of the memory cell area 100. The diffusion regions 7 and 7a were formed in the active region of the peripheral circuit/logic circuit area 300. The transistors were formed in the active regions of the memory cell area 100 and the peripheral circuit/logic circuit area 300 in the same processes.

An inter-layer insulator 31 of silicon nitride was formed over the substrate 10, so that the inter-layer insulator 31 covers the gate electrodes 4. An inter-layer insulator 21 of silicon oxide was formed over the inter-layer insulator 31. The inter-layer insulator 21 was planarized to form a flat upper surface. Contact holes were formed in the inter-layer insulator 21. The contact holes penetrate the inter-layer insulator 21. The contact holes were positioned over the diffusion regions 5 and 6 in the memory cell area 100, so that parts of the diffusion regions 5 and 6 were exposed to the contact holes. The other contact holes were positioned over the diffusion regions 7 and 7a in the peripheral circuit/logic circuit area 300, so that parts of the diffusion regions 7 and 7a were exposed to the contact holes. The contact holes in the memory cell area 100 and the peripheral circuit/logic circuit area 300 were filled with a polysilicon. The polysilicon contact the diffusion regions 5 and 6 in the memory cell area 100 and the conductive material contact the diffusion regions 7 and 7a in the peripheral circuit/logic circuit area 300. As a result, contact plugs 11, 11a, 14, and 14a were formed in the contact holes by the same processes. The contact plugs 11 11a were formed in the memory cell area 100. The contact plugs 14 and 14a were formed in the peripheral circuit/logic circuit area 300. The contact plugs 11 contact the diffusion regions 5 in the memory cell area 100. The contact plug 11a contacts the diffusion region 6 in the memory cell area 100. The contact plugs 41 contacts the diffusion region 7 in the peripheral circuit/logic circuit area 300. The contact plugs 41a contacts the diffusion region 7a in the peripheral circuit/logic circuit area 300.

A bit line 8 was in the memory cell area 100 and at the same time first level wiring layers 8a and 8b were in the peripheral circuit/logic circuit area 300.

An inter-layer insulator 22 of silicon oxide was formed over the inter-layer insulator 21, so that the inter-layer insulator 22 covers the bit line 8 and the first level wiring layers 8a and 8b. Contact holes were formed in the inter-layer insulator 22. The contact holes penetrate the inter-layer insulator 22. The contact holes are positioned over the contact plugs 11 in the memory cell area 100, so that parts of the contact plugs 11 are exposed to the contact holes. The other contact holes are positioned over the first level wiring layers 8a and 8b in the peripheral circuit/logic circuit area 300, so that parts of the first level wiring layers 8a and 8b are exposed to the contact holes.

A titanium film, a titanium nitride film, and a tungsten film were sequentially formed in the contact holes and over the inter-layer insulator 22. The staked films in the contact holes contacts the contact plugs 11 in the memory cell area 100 and the first level wiring layers 8a and 8b in the peripheral circuit/logic circuit area 300. The staked films were polished so that the staked films over the inter-layer insulator 22 were removed, while the staked films remain in the contact holes, thereby forming contact plugs 12 in the memory cell area 100 and contact plugs 42 and 42a in the peripheral circuit/logic circuit area 300.

A tungsten nitride film and a tungsten film were sequentially formed by a sputtering method over the inter-layer insulator 22 and over the contact plugs 12, 42 and 42a. The tungsten nitride film and the tungsten film were then patterned by a lithography process and a dry etching process, thereby forming landing pads 81 in the memory cell area 100, a base 81c in the boundary area 200, and local wirings 81a and 81b in the peripheral circuit/logic circuit area 300. The landing pads 81, the base 81c and local wirings 81a and 81b were concurrently formed by the same processes. The landing pads 81 contact the contact plugs 12 in the memory cell area 100. The base 81c was disposed over the inter-layer insulator 22 in the boundary area 200. The local wirings 81a and 81b contact the contact plugs 42 and 42a in the peripheral circuit/logic circuit area 300. As shown in FIG. 3, the landing pads 8 were disposed inside the base 81c which forms a frame surrounding the landing pads 8. The base 81c forms a rectangle frame in plan view. The landing pads 8 each have a circular shape in plan view.

An inter-layer insulator 32 of silicon nitride and having a thickness of 50 nm was formed by a low pressure chemical vapor deposition method over the inter-layer insulator 22, so that the inter-layer insulator 32 covers the landing pads 81, the base 81c and local wirings 81a and 81b. The inter-layer insulator 32 performed as an etching stopper. An inter-layer insulator 24 of silicon oxide and having a thickness of 1.5 micrometers was formed over the inter-layer insulator 32. An inter-layer insulator 36 of silicon nitride and having a thickness of 100 nm was formed over the inter-layer insulator 24 by an atomic layer deposition method at a growth temperature of 550° C.

As shown in FIGS. 5 and 6, capacitor holes 91 having a cylindrical shape with a diameter of 80 nm and a dummy bottom electrode groove 91a having a frame shape in plan view were formed in the multi-layered structure of the inter-layer insulators 32, 24 and 36 by a photo-lithography and a dry etching process. The capacitor holes 91 were formed in the memory cell area 100. The dummy bottom electrode groove 91a was formed in the boundary area 200. The dummy bottom electrode groove 91a surrounds in plan view the memory cell area 100 in which the capacitor holes 91 are formed.

As shown in FIG. 7, a conductive film 51b of titanium nitride having a thickness of 18 nm was formed by a chemical vapor deposition over the memory cell area 100, the boundary area 200 and the peripheral circuit/logic circuit area 300. The conductive film 51b was formed entirely over the memory cell area 100, the boundary area 200 and the peripheral circuit/logic circuit area 300. The conductive film 51b extends along the inside walls of the capacitor holes 91 in the memory cell area 100. The conductive film 51b extends along the inside walls of the dummy bottom electrode groove 91a in the boundary area 200. The conductive film 51b extends on the exposed portions of the landing pads 81 in the memory cell area 100. The conductive film 51b extends on the exposed portion of the base 81c in the boundary area 200. The conductive film 51b extends over the inter-layer insulator 36 in the memory cell area 100. The conductive film 51b extends over the inter-layer insulator 36a in the peripheral circuit/logic circuit area 300.

An inter-layer insulator 37 of silicon nitride was formed by a plasma chemical vapor deposition over the memory cell area 100, the boundary area 200 and the peripheral circuit/logic circuit area 300. The inter-layer insulator 37 extends over the conductive film 51b and fills shallower portions of the capacitor holes 91 in the memory cell area 100. The inter-layer insulator 37 extends over the conductive film 51b and fills a shallower portion of the dummy bottom electrode groove 91a in the boundary area 200. The inter-layer insulator 37 extends over the conductive film 51b in the peripheral circuit/logic circuit area 300. The capacitor holes 91 were filled with the inter-layer insulator 37 imperfectly. Only the shallower portions of the capacitor holes 91 were filled with the inter-layer insulator 37. The dummy bottom electrode groove 91a was filled with the inter-layer insulator 37 imperfectly. Only the shallower portion of the dummy bottom electrode groove 91a was filled with the inter-layer insulator 37.

As shown in FIGS. 8 and 9, a photo-resist pattern 101 was formed by a photolithograph process over the inter-layer insulator 37. The photo-resist pattern 101 extends over the memory cell area 100, the boundary area 200 and the peripheral circuit/logic circuit area 300. The photo-resist pattern 101 has an alignment of stripe-shaped openings 101a in the memory cell area 100.

As shown in FIG. 10, the photo-resist pattern 101 was used as a mask to carry out a dry etching process to selectively etch the inter-layer insulators 37 and 36 and the conductive film 51b, thereby forming windows 71, and making the beams of the inter-layer insulator 36. The beams of the inter-layer insulator 36 mechanically support the bottom electrodes 51. The inter-layer insulator 36a in the peripheral circuit/logic circuit area 300 was not etched by this etching process.

The photo-resist pattern 101 was removed by a know method such as an ashing process.

As shown in FIGS. 11 and 12, the inter-layer insulator 37 and the conductive film 51b were removed, except for the conductive film 51b which extends along the inside walls of the capacitor holes 91 and the dummy bottom electrode groove 91a so that the conductive film 51b remained only within the capacitor holes 91 and the dummy bottom electrode groove 91a. As a result, the remaining conductive films 51b in the capacitor holes 91 performed as the bottom electrodes 51, and the remaining conductive film 51b in the dummy bottom electrode groove 91a performed as the dummy bottom electrode 51a. Namely, the conductive film 51b and the dummy bottom electrode 51a were concurrently formed in the capacitor holes 91 and in the dummy bottom electrode 51a, respectively.

As shown in FIGS. 13 and 14, a wet etching process was carried out using a diluted hydrogen fluoride solution as an etchant and using the dummy bottom electrode 51a and the inter-layer insulators 32, 36 and 36a as etching stoppers, to etch the inter-layer insulator 24 in the memory cell area 100. Namely, the inter-layer insulator 24 surrounded by the dummy bottom electrode 51a was wet-etched by using the dummy bottom electrode 51a and the inter-layer insulators 32, 36 and 36a as etching stoppers.

As shown in FIG. 15, the bottom electrodes 51 and the dummy bottom electrode 51a were reduced in thickness by a wet etching process for 20 minutes using a commercially available etchant can be used, for example, N-311 which is available from Nagase ChemteX Corporation. The etchant N-311 mainly contains hydroxylamine, 2-aminoethanol (alkanolamines), and dimethyl sulfoxide. Hydroxylamine and 2-aminoethanol dissolve titanium nitride. The bottom electrodes 51 and the dummy bottom electrode 51a made of titanium nitride can be reduced in thickness by about 3 nm by the wet etching process using N-311 for about 20 min. The thickness of the bottom electrodes 51 and the dummy bottom electrode 51a was reduced to 15 nm. The inner diameter of the bottom electrodes 51 was increased to 50 nm.

As shown in FIG. 16, an aluminum oxide film and a zirconium oxide film were sequentially formed by an atomic layer deposition method. The capacitive insulating film 52 of the aluminum oxide film and the zirconium oxide film was formed which covers the bottom electrodes 51, the dummy bottom electrode 51a and the inter-layer insulator 36. The capacitive insulating film 52 has a thickness of 6 nm.

A top electrode layer 53 of titanium nitride having a thickness of 8 nm was formed by a chemical vapor deposition method, so that the top electrode layer 53 covers the capacitive insulating film 52. The top electrode layer 53 fills up the capacitive holes 91 and the dummy bottom electrode groove 91a. The top electrode layer 53 extends over the memory cell area 100, the boundary area 200 and the peripheral circuit/logic circuit area 300.

As shown in FIG. 17, in the boundary area 200 and the peripheral circuit/logic circuit area 300, there are a multi-layered structure which includes the inter-layer insulator 36a, the capacitive insulating film 52 and the top electrode layer 53. The multi-layered structure extends over the inter-layer insulator 24. In the peripheral circuit/logic circuit area 300, the multi-layered structure was selectively removed by a photo-lithography technique and a dry etching process, so that the inter-layer insulator 24 was exposed. The inter-layer insulator 36a, the capacitive insulating film 52 and the top electrode layer 53 remain in the boundary area 200. The inter-layer insulator 36, the capacitive insulating film 52 and the top electrode layer 53 remain in the memory cell area 100. As a result, the capacitors of crown shape having a height of 1.5 micrometers were defined in the memory cell area 100. Each capacitor includes the bottom electrode 51, the capacitive insulating film 52 and the top electrode layer 53. The capacitor may have a height of about 1.5 micrometers.

As shown in FIG. 18, an inter-layer insulator 25 of silicon oxide was formed over the top electrode layer 53 in the memory cell area 100 and the boundary area 200, and also over the inter-layer insulator 24 in the peripheral circuit/logic circuit area 300. The inter-layer insulator 25 extends over the top electrode layer 53 and the inter-layer insulator 24. The top surface of the top electrode layer 53 was higher than the top surface of the inter-layer insulator 24. The inter-layer insulator 25 has a difference in level between the boundary area 200 and the peripheral circuit/logic circuit area 300. The inter-layer insulator 25 was then planarized by a chemical mechanical polishing process. The inter-layer insulator 25 had a planarized surface.

As shown in FIG. 19, first, second and third contact holes were formed in the boundary area 200 and the peripheral circuit/logic circuit area 300. The first contact hole was formed in the boundary area 200. The first contact hole penetrates the inter-layer insulator 25 in the boundary area 200 so that the first contact hole reaches the top electrode 53 in the boundary area 200. The second contact hole was formed in the peripheral circuit/logic circuit area 300. The second contact hole penetrates the inter-layer insulators 25, 24 and 32 in the peripheral circuit/logic circuit area 300 so that the second contact hole reaches the local wiring 81a in the peripheral circuit/logic circuit area 300. The third contact hole was formed in the peripheral circuit/logic circuit area 300. The third contact hole penetrates the inter-layer insulators 25, 24 and 32 in the peripheral circuit/logic circuit area 300 so that the third contact hole reaches the local wiring 81b in the peripheral circuit/logic circuit area 300. A part of the top electrode 53 was exposed to the first contact hole. A part of the local wiring 81a was exposed to the second contact hole. A part of the local wiring 81b was exposed to the third contact hole.

A titanium nitride film and a tungsten film were sequentially formed which fills up the first, second and third contact holes and extends over the inter-layer insulator 25. The staked layer of the titanium nitride film and the tungsten film reaches the exposed part of the top electrode 53, the exposed part of the local wiring 81a, and the exposed part of the local wiring 81b. The staked layer of the titanium nitride film and the tungsten film contacts the top electrode 53, the local wiring 81a, and the local wiring 81b. The staked layer of the titanium nitride film and the tungsten film was removed by a chemical mechanical polishing process, except in the first, second and third contact holes, thereby forming contact plugs 44, 43 and 43a in the first, second and third contact holes, respectively. The contact plug 44 contacts the top electrode 53. The contact plug 43 contacts the local wiring 81a. The contact plug 43a contacts the local wiring 81b.

With reference again to FIG. 1, a titanium film, an aluminum film, and a titanium nitride film were formed over the contact plugs 43, 43a and 44, and the inter-layer insulator 25. The stacked conductive layer was patterned by a lithography technique and a dry etching process to form second level wirings 61 and 61a.

The second level wiring 61 runs over the inter-layer insulator 25. The second level wiring 61 contacts the contact plug 44. The second level wiring 61 was electrically connected through the contact plug 44 to the top electrode 53. The second level wiring 61 contacts the contact plug 43. The second level wiring 61 was electrically connected through the contact plug 43a, the local wiring 81b, the contact plug 42a, the first level writing 8b, and the contact plug 41a to the diffusion region 7a. The second level wiring 61 electrically connects the contact plug 44 and the contact plug 43. Thus, the top electrode 53 of the capacitors was eclectically connected through the contact plug 44, the second level wiring 61, the contact plug 43a, the local wiring 81b, the contact plug 42a, the first level writing 8b, and the contact plug 41a to the diffusion region 7a. In the memory cell area 100, the transistors were connected to the capacitors. The capacitors in the memory cell area 100 were electrically connected to the transistor in the peripheral circuit/logic circuit area 300.

The second level wiring 61a runs over the inter-layer insulator 24. The second level wiring 61a contacts the contact plug 43a. The second level wiring 61a was electrically connected through the contact plug 43a, the local wiring 81b, the contact plug 42a, the first level writing 8b and the contact plug 41a to the diffusion region 7a.

The number of the cavities in the inter-layer insulator 24 that are positioned outside the dummy bottom electrode groove 91a was investigated for the above-described semiconductor devices with the conductive film 51b of 18 nm thickness. It was confirmed that the number of the cavities over the silicon substrate 10 is not more than 100 per wafer.

### Example 2

The semiconductor devices which are the same as the above-described semiconductor device of Example 1 were formed, provided that the thickness of the conductive film 51b was changed from 18 nm. There were formed semiconductor devices having different thicknesses of 16 nm, 20 nm, 22 nm and 24 nm. The number of the cavities in the inter-layer insulator 24 that are positioned outside the dummy bottom electrode groove 91a was investigated for the semiconductor devices having the different thicknesses. FIG. 20 is a diagram illustrating the number of cavities per wafer over thicknesses of the conductive films in the semiconductor devices. The number of the cavities over the silicon substrate 10 per wafer was plotted in FIG. 20 for the semiconductor devices having the different thicknesses. FIG. 20 demonstrates that the thickness of the conductive film 51b is preferably at least 18 nm and more preferably not less than 20 nm in view of reducing the number of cavities in the inter-layer insulator 24.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

It is apparent that the present invention is not limited to the above embodiments, but may be modified and changed without departing from the scope and spirit of the invention.

What is claimed is:

1. A method of forming a semiconductor device, the method comprising:
forming at least one capacitor hole and a groove in an insulating film, the at least one capacitor hole being in a memory cell area, the groove surrounding the memory cell area in plan view;
forming conductive films at least in the at least one capacitor hole and in the groove;
carrying out an etching process using the conductive films as etching stoppers to selectively remove the insulating film in the memory cell area, while leaving the insulating film outside the groove; and
reducing a thickness of at least the conductive film in the at least one capacitor hole.

2. The method as claimed in claim 1, wherein reducing the thickness of at least the conductive film comprises reducing thicknesses of the conductive films in the at least one capacitor hole and in the groove.

3. The method as claimed in claim 2, wherein the thicknesses of the conductive films in the at least one capacitor hole and in the groove are concurrently reduced.

4. The method as claimed in claim 1, wherein forming the conductive films comprises:
forming a conductive film along inside walls of the at least one capacitor hole and inside walls of the groove and along a surface of the insulating film, the conductive film extending over the memory cell area, a boundary area and a peripheral circuit area, the boundary area surrounding the memory cell area in plan view, the boundary area having the groove, the peripheral circuit area surrounding the boundary area in plan view; and
selectively removing the conductive film, to leave the conductive film along the inside walls of the at least one capacitor hole and along the inside walls of the groove.

5. The method as claimed in claim 4, wherein selectively removing the conductive film is carried out after carrying out the etching process and before reducing the thickness of the at least the conductive film.

6. The method as claimed in claim 1, wherein the thickness of at least the conductive film before reducing the thickness thereof is at least 18 nm, and the thickness of at least the conductive film after reducing the thickness thereof is less than 18 nm.

7. The method as claimed in claim 1, wherein reducing a thickness of at least the conductive film comprises a wet etching process.

8. The method as claimed in claim 1, wherein reducing a thickness of at least the conductive film comprises a dry etching process.

9. A method of forming a semiconductor device, the method comprising:
preparing a semiconductor substrate which has a memory cell area, a boundary area, and a peripheral circuit area, the boundary area surrounding the memory cell area in plan view, the peripheral circuit area surrounding the boundary area;
forming an inter-layer insulator which extends over the memory cell area, the boundary area, and the peripheral circuit area;
forming at least one capacitor hole in the inter-layer insulator in the memory cell area;
forming a dummy bottom electrode groove in the inter-layer insulator in the boundary area;
forming conductive films at least in the at least one capacitor hole and in the groove;
carrying out a wet etching process using the conductive films as etching stoppers to selectively remove the insulating film in the memory cell area, while leaving the insulating film outside the groove; and
reducing a thickness of at least the conductive film in the at least one capacitor hole.

10. The method as claimed in claim 9, wherein reducing the thickness of at least the conductive film comprises reducing thicknesses of the conductive films in the at least one capacitor hole and in the groove concurrently.

11. The method as claimed in claim 9, wherein forming the conductive films comprises:
forming a conductive film along inside walls of the at least one capacitor hole and inside walls of the groove and along a surface of the insulating film, the conductive film extending over the memory cell area, the boundary area and the peripheral circuit area; and
selectively removing the conductive film, to leave the conductive film along the inside walls of the at least one capacitor hole and along the inside walls of the groove, selectively removing the conductive film being carried out before carrying out the etching process.

12. The method as claimed in claim 9, wherein forming the conductive films comprises:
forming a conductive film along inside walls of the at least one capacitor hole and inside walls of the groove and along a surface of the insulating film, the conductive film extending over the memory cell area, the boundary area and the peripheral circuit area; and
selectively removing the conductive film, to leave the conductive film along the inside walls of the at least one capacitor hole and along the inside walls of the groove, selectively removing the conductive film being carried out after carrying out the etching process and before reducing the thickness of the at least the conductive film.

13. The method as claimed in claim 9, further comprising:
forming a capacitive insulation film on at least the conductive film in the at least one capacitor hole; and
forming a top electrode on the capacitive insulation film, the top electrode being separated by the capacitive insulation film from the conductive film in the capacitor hole, the conductive film performing as a bottom electrode of a capacitor.

14. The method as claimed in claim 9, further comprising:
forming an anti-etching film over the inter-layer insulator, before forming the at least one capacitor hole and before forming the dummy bottom electrode groove; and
selectively removing the anti-etching film in the memory cell area before carrying out the etching process,
wherein forming the at least one capacitor hole comprises forming at least one capacitor hole which penetrates the anti-etching film and the inter-layer insulator in the memory cell area,
wherein forming the dummy bottom electrode groove comprises forming a dummy bottom electrode groove which penetrates the anti-etching film and the inter-layer insulator in the boundary area, and
wherein carrying out the etching process comprises carrying out a wet etching process using the conductive films and the anti-etching film as etching stoppers to selectively remove the insulating film in the memory cell area, while leaving the insulating film outside the groove.

15. The method as claimed in claim 14, wherein the conductive films comprise titanium nitride films, the insulating film comprises a silicon oxide film, and the anti-etching film comprises a silicon nitride film.

16. The method as claimed in claim 9, further comprising:
forming an etching stopper insulating film over the semiconductor substrate before forming the inter-layer insulator, the etching stopper insulating film extending over the memory cell area, the boundary area, and the peripheral circuit area,
wherein forming the inter-layer insulator comprises forming the inter-layer insulator over the etching stopper insulating film;
wherein forming the at least one capacitor hole comprises forming at least one capacitor hole which penetrates the inter-layer insulator and the etching stopper insulating film in the memory cell area,
wherein forming the dummy bottom electrode groove comprises forming a dummy bottom electrode groove which penetrates the inter-layer insulator and the etching stopper insulating film in the boundary area, and
wherein carrying out the etching process comprises carrying out a wet etching process using the conductive films and the etching stopper insulating film as etching stoppers to selectively remove the insulating film in the memory cell area, while leaving the insulating film outside the groove.

17. The method as claimed in claim 16, wherein the conductive films comprise titanium nitride films, the insulating film comprises a silicon oxide film, and the etching stopper insulating film comprises a silicon nitride film.

18. The method as claimed in claim 9, wherein the thickness of at least the conductive film before reducing the thickness thereof is at least 18 nm, and the thickness of at least the conductive film after reducing the thickness thereof is less than 18 nm.

19. A method of forming a semiconductor device, the method comprising:
forming a hole in an insulating film;
forming a first conductive film in the hole;
removing at least a portion of the insulating film around the first conductive film; and
reducing a thickness of the first conductive film to produce a second conductive film.

20. The method as claimed in claim 19, further comprising:
forming a dielectric film on the second conductive film; and
forming a third conductive film, the second and third conductive films and the dielectric film constitute a capacitor.
